(19) United States
(12) Patent Application Publication
(10) Pub. No.: US 2025/0337524 A1
(43) Pub. Date: Oct. 30, 2025

(54) METHODS, SYSTEM, AND APPARATUS FOR JOINT ERROR CORRECTION CODING OF A SELF-DECODABLE PAYLOAD AND A COMBINED PAYLOAD

(71) Applicant: Huawei Technologies Co., Ltd., Shenzhen (CN)

(72) Inventors: Huazi Zhang, Hangzhou (CN); Xiaoyan Bi, Shanghai (CN); Yan Chen, Kanata (CA); Jianglei Ma, Ottawa (CA); Wen Tong, Ottawa (CA)

(21) Appl. No.: 19/228,213

(22) Filed: Jun. 4, 2025

Related U.S. Application Data
(63) Continuation of application No. PCT/CN2022/136792, filed on Dec. 6, 2022.

(51) Int. Cl. H04L 1/00

(52) U.S. Cl. CPC H04L 1/0057; H04L 1/0003; H04L 1/0009; H04L 1/0041; H04L 1/007

(57) ABSTRACT

Joint error correction coding involves error correction encoding of multiple individual payloads to generate a codeword. The codeword includes a self-decodable encoded block generated by error correction encoding a first individual payload, and another encoded block generated by error correction encoding a second individual payload with which a portion of the first individual payload is combined. The portion of the first individual payload that is to be combined with the second individual payload is determined based on an ordering of bits of the first individual payload. The individual payloads or encoded blocks are decodable independently of each other, and the self-decodable encoded block and the other encoded block are also jointly decodable.

### CROSS-REFERENCE TO RELATED APPLICATION

This application is a continuation of International Application No. PCT/CN2022/136792, entitled “METHODS, SYSTEM, AND APPARATUS FOR JOINT ERROR CORRECTION CODING OF A SELF-DECODABLE PAYLOAD AND A COMBINED PAYLOAD” and filed on Dec. 6, 2022, the disclosure of which is hereby incorporated by reference in its entirety.

### TECHNICAL FIELD

The present application relates to error correction coding for wireless communications.

### BACKGROUND

Resilience is a fundamental feature that needs to be addressed for so-called sixth generation (6G) communications. According to some technology visions of future factories and industries, for example, ultra-reliable and low latency wireless communications are a pivotal enabler for automated manufacturing on a massive scale.

Two trends are also observed in recent developments toward 6G. From a technological perspective, millimeter-wavelength (mmWave) communications and massive multiple input multiple output (MIMO) may become more prevalent because they can significantly expand current bandwidth resources. From a service perspective, a single communication device will likely need to support multiple services with different latency and reliability requirements.

A potential scenario emerges as multiple services converge into one physical wireless link. The purpose is to deliver multiple quality of service (QoS) levels to multiple services within only one wireless link. Given high carrier frequency and massive number of antennas in some communication systems, beamforming can be done more aggressively, enabling the convergence of multiple services into one wireless link. Meanwhile, these services may have very diverse key performance indicators (KPIs). For example, ultra-reliable low latency communications (URLLC), massive machine type communications (mMTC), enhanced mobile broadband (eMBB) and terabit per second (Tbps) communications may all be integrated in one link. This is challenging because different KPIs, for example for signal to noise ratio (SNR), fading, etc., must be supported under the same wireless channel.

### SUMMARY

The present disclosure encompasses embodiments that may be useful in addressing various technical shortcomings of current coding methods. With current technologies, there is a tradeoff between ultra-reliable communication and low latency communication. To achieve ultra-reliability, hybrid automatic repeat request (HARQ) has been employed in current systems to reduce the block error rate (BLER) level by several order of magnitudes. However, round-trip delay incurred by negative acknowledgement (NACK) signaling, re-scheduling and retransmission may not meet low-latency requirements in 6G. A simple workaround is to reduce code rate and modulation order, but this comes at a cost of spectrum efficiency, and is generally discouraged in system design.

A previous disclosure, International Patent Application No. PCT/CN2022/122852, filed Sep. 29, 2022, proposes a coding approach to enhance reliability without requesting a retransmission after a decoding failure. A second, joint decoding attempt is made after a decoding failure, to decode using received symbols of multiple coupled codewords, instead of newly retransmitted symbols received in response to a HARQ NACK. This type of approach may be referred to as a HARQ-less approach, in that a retransmission is not automatically requested immediately after a decoding failure.

Some types of hard-output (also known as hard-decision) decoders perform sequential decisions on information bits of a codeword. Once a code bit is hard-decoded, the decision on that bit cannot be reverted. This may, for example, create a challenge in supporting a second decoding attempt according to the HARQ-less coding approach referenced above.

Providing good coding performance in mixed-service and low-latency communication applications remains a challenge. For example, HARQ-based approaches may incur long round-trip delay and might not be able to meet low latency requirements, and hard-output decoding might not work well in the above-referenced HARQ-less coding approach to enhance reliability without requesting a retransmission after a decoding failure.

The present disclosure includes detailed encoding and decoding embodiments that are particularly suited to joint forward error correction (FEC) coding that involves multiple coupled codewords. In each codeword, either bit-by-bit hard decision, or block-by-block hard decision may be supported. Self-decoding of a single codeword and enhanced joint decoding of multiple codewords may be enabled by coupling codewords with shared payload bits, which may be or include information bits, systematic bits, or code bits.

In some embodiments of the present disclosure, retransmission latency may be mitigated or avoided in conjunction by supporting further decoding operations in hard-output decoding after a decoding failure of a delay-sensitive payload. Requesting a retransmission may not be feasible in some applications because a resulting round-trip delay may exceed a maximum tolerable delay, and further decoding operations after decoding failure, which is not possible according to hard-output decoding approaches in which a hard decision cannot be reverted once made, may avoid a retransmission request. For example, extra decoding latency incurred during a second decoding attempt without requesting a retransmission is likely to be much smaller than the extra latency of round-trip delay for a retransmission.

Joint coding according to some embodiments may help enhance performance for hard-output decoding implementations, in that multiple services may in effect augment each other in joint coding.

Unequal error protection may be provided for different payloads, such as payloads related to different services. For example, target BLER of a URLLC payload may be at least one order of magnitude lower than that of an eMBB payload. Embodiments disclosed herein may enable such unequal error protection, even for hard-output decoding applications.

Self-decodability, for each individual service for example, may also or instead be provided. To support different latency requirements of multiple services, each service may be self-decodable based on its own proportion of code bits in a codeword, or in other words based on its own corresponding part of a longer codeword. For example, it may be possible to decode a shorter URLLC payload once some, but not all, code bits (such as log-likelihood ratios or LLRs) of a longer codeword are received. Payloads may thus be self-decodable, without having to wait for the reception of an entire, longer, joint codeword. Embodiments disclosed herein may provide such self-decodability and/or joint-decodability for hard-output decoding.

According to an aspect of the present disclosure, a method involves transmitting, by a first communication device to a second communication device in a wireless communication network, a codeword comprising multiple encoded blocks generated by error correction encoding respective individual payloads. The encoded blocks include a self-decodable encoded block generated by error correction encoding a first individual payload, and another encoded block generated by error correction encoding a second individual payload with which a portion of the first individual payload is combined for error correction encoding.

Another method involves obtaining a first individual payload and a second individual payload; error correction encoding the first individual payload to generate a self-decodable encoded block; error correction encoding the second individual payload with which a portion of the first individual payload is combined for error correction encoding, to generate another encoded block; and outputting a codeword that includes the self-decodable encoded block and the other encoded block.

In such methods, the portion of the first individual payload may be determined for combining with the second individual payload based on an ordering of bits of the first individual payload. The self-decodable encoded block is decodable independently of the other encoded block, and is further decodable jointly with the other encoded block.

A further method embodiment involves receiving, from a first communication device by a second communication device in a wireless communication network, a codeword that includes multiple encoded blocks generated by error correction encoding respective individual payloads. The encoded blocks, as described above, include a self-decodable encoded block generated by error correction encoding a first individual payload, and another encoded block generated by error correction encoding a second individual payload with which a portion of the first individual payload is combined for error correction encoding.

A method may involve decoding a first individual payload and a second individual payload from a codeword that includes a self-decodable encoded block generated by error correction encoding the first individual payload and another encoded block generated by error correction encoding the second individual payload with which a portion of the first individual payload is combined; and outputting the first individual payload and the second individual payload.

As in other method embodiments, the portion of the first individual payload may be determined for combining with the second individual payload based on an ordering of bits of the first individual payload, and the self-decodable encoded block is decodable independently of the other encoded block and is further decodable jointly with the other encoded block.

In apparatus embodiments, an apparatus may include a processor and a non-transitory computer readable storage medium that is coupled to the processor. The non-transitory computer readable storage medium stores programming for execution by the processor.

A storage medium need not necessarily or only be implemented in or in conjunction with such an apparatus. A computer program product, for example, may be or include a non-transitory computer readable medium storing programming for execution by a processor.

Programming stored by a computer readable storage medium may include instructions to, or to cause a processor to, perform, implement, support, or enable any of the methods disclosed herein.

For example, the programming may include instructions to, or to cause a processor to: transmit, by a first communication device to a second communication device in a wireless communication network, a codeword that includes multiple encoded blocks generated by error correction encoding respective individual payloads; or to receive, from a first communication device by a second communication device in a wireless communication network, a codeword that includes multiple encoded blocks generated by error correction encoding respective individual payloads. The encoded blocks include a self-decodable encoded block generated by error correction encoding a first individual payload, and another encoded block generated by error correction encoding a second individual payload with which a portion of the first individual payload is combined for error correction encoding.

Programming may include instructions to, or to cause a processor to: obtain a first individual payload and a second individual payload; error correction encode the first individual payload to generate a self-decodable encoded block; error correction encode the second individual payload with which a portion of the first individual payload is combined for error correction encoding, to generate another encoded block; and output a codeword that includes the self-decodable encoded block and the other encoded block.

According to another aspect of the present disclosure, programming may include instructions to, or to cause a processor to: decode a first individual payload and a second individual payload from a codeword that includes a self-decodable encoded block generated by error correction encoding the first individual payload and another encoded block generated by error correction encoding the second individual payload with which a portion of the first individual payload is combined; and output the first individual payload and the second individual payload.

In any of these programming examples, the portion of the first individual payload may be determined for combining with the second individual payload based on an ordering of bits of the first individual payload, and the self-decodable encoded block is decodable independently of the other encoded block and is further decodable jointly with the other encoded block.

A system is also disclosed, and may include a first communication device and a second communication device. The first communication device is configured to transmit a codeword that includes multiple encoded blocks generated by encoding respective individual payloads with an error correction code. The encoded blocks include a self-decodable encoded block generated by error correction encoding a first individual payload, and another encoded block generated by error correction encoding a second individual payload with which a portion of the first individual payload is combined for error correction encoding. The second communication device is configured to receive, from the first communication device, the codeword that includes the encoded blocks, and to decode the self-decodable encoded block to obtain the first individual payload from the codeword. As in other embodiments, the portion of the first individual payload may be determined for combining with the second individual payload based on an ordering of bits of the first individual payload.

The present disclosure encompasses these and other aspects or embodiments.

### BRIEF DESCRIPTION OF THE DRAWINGS

For a more complete understanding of the present embodiments, and the advantages thereof, reference is now made, by way of example, to the following descriptions taken in conjunction with the accompanying drawings.

FIG. 1 is a simplified schematic illustration of a communication system.

FIG. 2 is a block diagram illustration of the example communication system in FIG. 1.

FIG. 3 illustrates an example electronic device and examples of base stations.

FIG. 4 illustrates units or modules in a device.

FIG. 5 is a block diagram illustrating an example multi-service scenario.

FIG. 6 is a block diagram illustrating encoding and decoding according to an embodiment.

FIG. 7 is a block diagram illustrating an example of encoding according to an embodiment.

FIG. 8 is a block diagram illustrating an example of decoding according to an embodiment.

FIG. 9 is a block diagram of an example encoding chain according to an embodiment.

FIG. 10 is a flow diagram illustrating example methods according to embodiments.

FIG. 11 is a plot of simulation results.

### DETAILED DESCRIPTION

For illustrative purposes, specific example embodiments will now be explained in greater detail in conjunction with the figures.

The embodiments set forth herein represent information sufficient to practice the claimed subject matter and illustrate ways of practicing such subject matter. Upon reading the following description in light of the accompanying figures, those of skill in the art will understand the concepts of the claimed subject matter and will recognize applications of these concepts not particularly addressed herein. It should be understood that these concepts and applications fall within the scope of the disclosure and the accompanying claims.

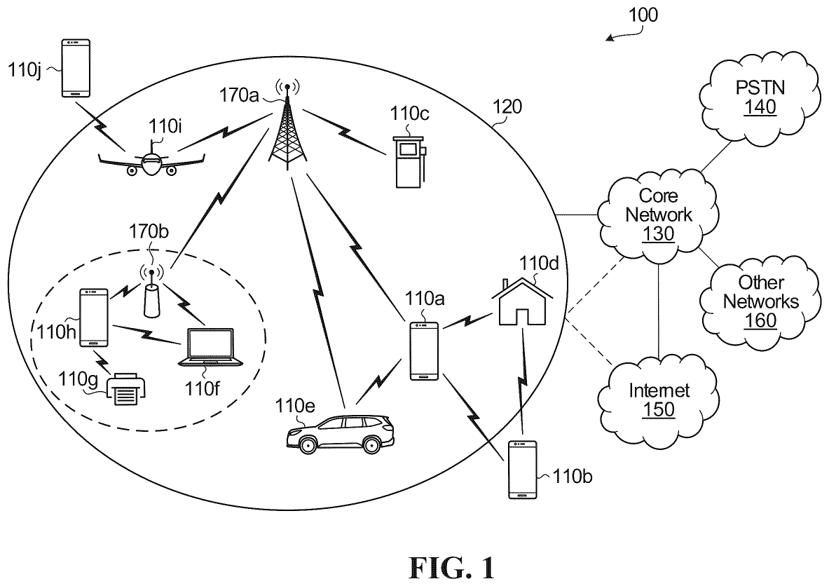

Referring to FIG. 1, as an illustrative example without limitation, a simplified schematic illustration of a communication system is provided. The communication system 100 comprises a radio access network 120. The radio access network 120 may be a next generation (e.g., sixth generation, “6G,” or later) radio access network, or a legacy (e.g., 5G, 4G, 3G or 2G) radio access network. One or more communication electric device (ED) 110a, 110b, 110c, 110d, 110e, 110f, 110g, 110h, 110i, 110j (generically referred to as 110) may be interconnected to one another or connected to one or more network nodes (170a, 170b, generically referred to as 170) in the radio access network 120. A core network 130 may be a part of the communication system and may be dependent or independent of the radio access technology used in the communication system 100. Also the communication system 100 comprises a public switched telephone network (PSTN) 140, the internet 150, and other networks 160.

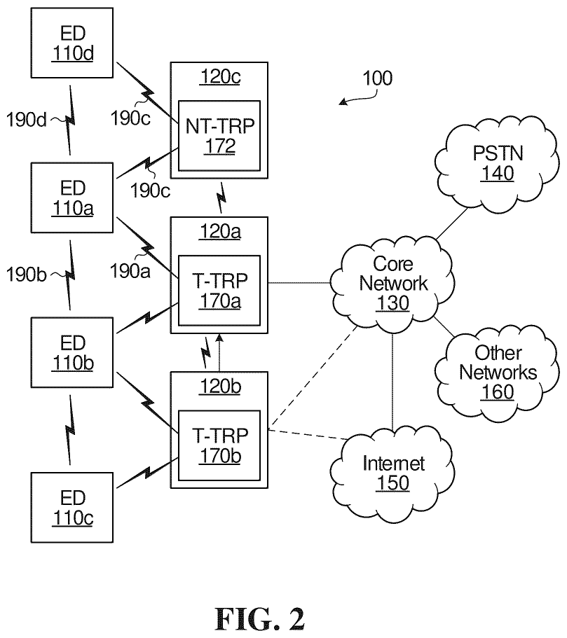

FIG. 2 illustrates an example communication system 100. In general, the communication system 100 enables multiple wireless or wired elements to communicate data and other content. The purpose of the communication system 100 may be to provide content, such as voice, data, video, and/or text, via broadcast, multicast and unicast, etc. The communication system 100 may operate by sharing resources, such as carrier spectrum bandwidth, between its constituent elements. The communication system 100 may include a terrestrial communication system and/or a non-terrestrial communication system. The communication system 100 may provide a wide range of communication services and applications (such as earth monitoring, remote sensing, passive sensing and positioning, navigation and tracking, autonomous delivery and mobility, etc.). The communication system 100 may provide a high degree of availability and robustness through a joint operation of a terrestrial communication system and a non-terrestrial communication system. For example, integrating a non-terrestrial communication system (or components thereof) into a terrestrial communication system can result in what may be considered a heterogeneous network comprising multiple layers. Compared to conventional communication networks, the heterogeneous network may achieve better overall performance through efficient multi-link joint operation, more flexible functionality sharing and faster physical layer link switching between terrestrial networks and non-terrestrial networks.

The terrestrial communication system and the non-terrestrial communication system could be considered sub-systems of the communication system. In the example shown in FIG. 2, the communication system 100 includes electronic devices (ED) 110a, 110b, 110c, 110d (generically referred to as ED 110), radio access networks (RANs) 120a, 120b, a non-terrestrial communication network 120c, a core network 130, a public switched telephone network (PSTN) 140, the Internet 150 and other networks 160. The RANs 120a, 120b include respective base stations (BSs) 170a, 170b, which may be generically referred to as terrestrial transmit and receive points (T-TRPs) 170a, 170b. The non-terrestrial communication network 120c includes an access node 172, which may be generically referred to as a non-terrestrial transmit and receive point (NT-TRP) 172.

Any ED 110 may be alternatively or additionally configured to interface, access, or communicate with any T-TRP 170a, 170b and NT-TRP 172, the Internet 150, the core network 130, the PSTN 140, the other networks 160, or any combination of the preceding. In some examples, the ED 110a may communicate an uplink and/or downlink transmission over a terrestrial air interface 190a with T-TRP 170a. In some examples, the Eds 110a, 110b, 110c and 110d may also communicate directly with one another via one or more sidelink air interfaces 190b. In some examples, the ED 110d may communicate an uplink and/or downlink transmission over a non-terrestrial air interface 190c with NT-TRP 172.

The air interfaces 190a and 190b may use similar communication technology, such as any suitable radio access technology. For example, the communication system 100 may implement one or more channel access methods, such as code division multiple access (CDMA), space division multiple access (SDMA), time division multiple access (TDMA), frequency division multiple access (FDMA), orthogonal FDMA (OFDMA), or single-carrier FDMA (SC-FDMA) in the air interfaces 190a and 190b. The air interfaces 190a and 190b may utilize other higher dimension signal spaces, which may involve a combination of orthogonal and/or non-orthogonal dimensions.

The non-terrestrial air interface 190c can enable communication between the ED 110d and one or multiple NT-TRPs 172 via a wireless link or simply a link. For some examples, the link is a dedicated connection for unicast transmission, a connection for broadcast transmission, or a connection between a group of Eds 110 and one or multiple NT-TRPs 175 for multicast transmission.

The RANs 120a and 120b are in communication with the core network 130 to provide the Eds 110a, 110b, 110c with various services such as voice, data and other services. The RANs 120a and 120b and/or the core network 130 may be in direct or indirect communication with one or more other RANs (not shown), which may or may not be directly served by core network 130 and may, or may not, employ the same radio access technology as RAN 120a, RAN 120b or both. The core network 130 may also serve as a gateway access between (i) the RANs 120a and 120b or the Eds 110a, 110b, 110c or both, and (ii) other networks (such as the PSTN 140, the Internet 150, and the other networks 160). In addition, some or all of the Eds 110a, 110b, 110c may include functionality for communicating with different wireless networks over different wireless links using different wireless technologies and/or protocols. Instead of wireless communication (or in addition thereto), the Eds 110a, 110b, 110c may communicate via wired communication channels to a service provider or switch (not shown) and to the Internet 150. The PSTN 140 may include circuit switched telephone networks for providing plain old telephone service (POTS). The Internet 150 may include a network of computers and subnets (intranets) or both and incorporate protocols, such as Internet Protocol (IP), Transmission Control Protocol (TCP), User Datagram Protocol (UDP). The Eds 110a, 110b, 110c may be multimode devices capable of operation according to multiple radio access technologies and may incorporate multiple transceivers necessary to support such.

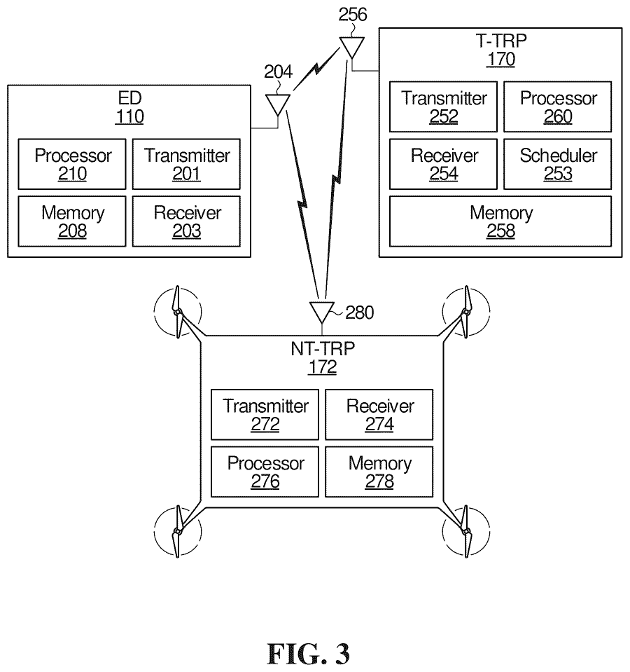

FIG. 3 illustrates another example of an ED 110 and a base station 170a, 170b and/or 170c. The ED 110 is used to connect persons, objects, machines, etc. The ED 110 may be widely used in various scenarios, for example, cellular communications, device-to-device (D2D), vehicle to everything (V2X), peer-to-peer (P2P), machine-to-machine (M2M), machine-type communications (MTC), Internet of things (IOT), virtual reality (VR), augmented reality (AR), industrial control, self-driving, remote medical, smart grid, smart furniture, smart office, smart wearable, smart transportation, smart city, drones, robots, remote sensing, passive sensing, positioning, navigation and tracking, autonomous delivery and mobility, etc.

Each ED 110 represents any suitable end user device for wireless operation and may include such devices (or may be referred to) as a user equipment/device (UE), a wireless transmit/receive unit (WTRU), a mobile station, a fixed or mobile subscriber unit, a cellular telephone, a station (STA), a machine type communication (MTC) device, a personal digital assistant (PDA), a smartphone, a laptop, a computer, a tablet, a wireless sensor, a consumer electronics device, a smart book, a vehicle, a car, a truck, a bus, a train, or an IoT device, an industrial device, or apparatus (e.g., communication module, modem, or chip) in the forgoing devices, among other possibilities. Future generation Eds 110 may be referred to using other terms. The base stations 170a and 170b each T-TRPs and will, hereafter, be referred to as T-TRP 170. Also shown in FIG. 3, a NT-TRP will hereafter be referred to as NT-TRP 172. Each ED 110 connected to the T-TRP 170 and/or the NT-TRP 172 can be dynamically or semi-statically turned-on (i.e., established, activated or enabled), turned-off (i.e., released, deactivated or disabled) and/or configured in response to one of more of: connection availability; and connection necessity.

The ED 110 includes a transmitter 201 and a receiver 203 coupled to one or more antennas 204. Only one antenna 204 is illustrated. One, some, or all of the antennas 204 may, alternatively, be panels. The transmitter 201 and the receiver 203 may be integrated, e.g., as a transceiver. The transceiver is configured to modulate data or other content for transmission by the at least one antenna 204 or by a network interface controller (NIC). The transceiver may also be configured to demodulate data or other content received by the at least one antenna 204. Each transceiver includes any suitable structure for generating signals for wireless or wired transmission and/or processing signals received wirelessly or by wire. Each antenna 204 includes any suitable structure for transmitting and/or receiving wireless or wired signals.

The ED 110 includes at least one memory 208. The memory 208 stores instructions and data used, generated, or collected by the ED 110. For example, the memory 208 could store software instructions or modules configured to implement some or all of the functionality and/or embodiments described herein and that are executed by one or more processing unit(s) (e.g., a processor 210). Each memory 208 includes any suitable volatile and/or non-volatile storage and retrieval device(s). Any suitable type of memory may be used, such as random access memory (RAM), read only memory (ROM), hard disk, optical disc, subscriber identity module (SIM) card, memory stick, secure digital (SD) memory card, on-processor cache and the like.

The ED 110 may further include one or more input/output devices (not shown) or interfaces (such as a wired interface to the Internet 150 in FIG. 1). The input/output devices permit interaction with a user or other devices in the network. Each input/output device includes any suitable structure for providing information to, or receiving information from, a user, such as through operation as a speaker, a microphone, a keypad, a keyboard, a display or a touch screen, including network interface communications.

The ED 110 includes the processor 210 for performing operations including those operations related to preparing a transmission for uplink transmission to the NT-TRP 172 and/or the T-TRP 170, those operations related to processing downlink transmissions received from the NT-TRP 172 and/or the T-TRP 170, and those operations related to processing sidelink transmission to and from another ED 110. Processing operations related to preparing a transmission for uplink transmission may include operations such as encoding, modulating, transmit beamforming and generating symbols for transmission. Processing operations related to processing downlink transmissions may include operations such as receive beamforming, demodulating and decoding received symbols. Depending upon the embodiment, a downlink transmission may be received by the receiver 203, possibly using receive beamforming, and the processor 210 may extract signaling from the downlink transmission (e.g., by detecting and/or decoding the signaling). An example of signaling may be a reference signal transmitted by the NT-TRP 172 and/or by the T-TRP 170. In some embodiments, the processor 210 implements the transmit beamforming and/or the receive beamforming based on the indication of beam direction, e.g., beam angle information (BAI), received from the T-TRP 170. In some embodiments, the processor 210 may perform operations relating to network access (e.g., initial access) and/or downlink synchronization, such as operations relating to detecting a synchronization sequence, decoding and obtaining the system information, etc. In some embodiments, the processor 210 may perform channel estimation, e.g., using a reference signal received from the NT-TRP 172 and/or from the T-TRP 170.

Although not illustrated, the processor 210 may form part of the transmitter 201 and/or part of the receiver 203. Although not illustrated, the memory 208 may form part of the processor 210.

The processor 210, the processing components of the transmitter 201 and the processing components of the receiver 203 may each be implemented by the same or different one or more processors that are configured to execute instructions stored in a memory (e.g., the in memory 208). Alternatively, some or all of the processor 210, the processing components of the transmitter 201 and the processing components of the receiver 203 may each be implemented using dedicated circuitry, such as a programmed field-programmable gate array (FPGA), a graphical processing unit (GPU), or an application-specific integrated circuit (ASIC).

The T-TRP 170 may be known by other names in some implementations, such as a base station, a base transceiver station (BTS), a radio base station, a network node, a network device, a device on the network side, a transmit/receive node, a Node B, an evolved NodeB (eNodeB or eNB), a Home eNodeB, a next Generation NodeB (gNB), a transmission point (TP), a site controller, an access point (AP), a wireless router, a relay station, a remote radio head, a terrestrial node, a terrestrial network device, a terrestrial base station, a base band unit (BBU), a remote radio unit (RRU), an active antenna unit (AAU), a remote radio head (RRH), a central unit (CU), a distribute unit (DU), a positioning node, among other possibilities. The T-TRP 170 may be a macro BS, a pico BS, a relay node, a donor node, or the like, or combinations thereof. The T-TRP 170 may refer to the forgoing devices or refer to apparatus (e.g., a communication module, a modem or a chip) in the forgoing devices.

In some embodiments, the parts of the T-TRP 170 may be distributed. For example, some of the modules of the T-TRP 170 may be located remote from the equipment that houses antennas 256 for the T-TRP 170, and may be coupled to the equipment that houses antennas 256 over a communication link (not shown) sometimes known as front haul, such as common public radio interface (CPRI). Therefore, in some embodiments, the term T-TRP 170 may also refer to modules on the network side that perform processing operations, such as determining the location of the ED 110, resource allocation (scheduling), message generation, and encoding/decoding, and that are not necessarily part of the equipment that houses antennas 256 of the T-TRP 170. The modules may also be coupled to other T-TRPs. In some embodiments, the T-TRP 170 may actually be a plurality of T-TRPs that are operating together to serve the ED 110, e.g., through the use of coordinated multipoint transmissions.

The T-TRP 170 includes at least one transmitter 252 and at least one receiver 254 coupled to one or more antennas 256. Only one antenna 256 is illustrated. One, some, or all of the antennas 256 may, alternatively, be panels. The transmitter 252 and the receiver 254 may be integrated as a transceiver. The T-TRP 170 further includes a processor 260 for performing operations including those related to: preparing a transmission for downlink transmission to the ED 110; processing an uplink transmission received from the ED 110; preparing a transmission for backhaul transmission to the NT-TRP 172; and processing a transmission received over backhaul from the NT-TRP 172. Processing operations related to preparing a transmission for downlink or backhaul transmission may include operations such as encoding, modulating, precoding (e.g., multiple input multiple output (MIMO) precoding), transmit beamforming and generating symbols for transmission. Processing operations related to processing received transmissions in the uplink or over backhaul may include operations such as receive beamforming, demodulating received symbols and decoding received symbols. The processor 260 may also perform operations relating to network access (e.g., initial access) and/or downlink synchronization, such as generating the content of synchronization signal blocks (SSBs), generating the system information, etc. In some embodiments, the processor 260 also generates an indication of beam direction, e.g., BAI, which may be scheduled for transmission by a scheduler 253. The processor 260 performs other network-side processing operations described herein, such as determining the location of the ED 110, determining where to deploy the NT-TRP 172, etc. In some embodiments, the processor 260 may generate signaling, e.g., to configure one or more parameters of the ED 110 and/or one or more parameters of the NT-TRP 172. Any signaling generated by the processor 260 is sent by the transmitter 252. Note that “signaling,” as used herein, may alternatively be called control signaling. Dynamic signaling may be transmitted in a control channel, e.g., a physical downlink control channel (PDCCH) and static, or semi-static, higher layer signaling may be included in a packet transmitted in a data channel, e.g., in a physical downlink shared channel (PDSCH).

The scheduler 253 may be coupled to the processor 260. The scheduler 253 may be included within, or operated separately from, the T-TRP 170. The scheduler 253 may schedule uplink, downlink and/or backhaul transmissions, including issuing scheduling grants and/or configuring scheduling-free (“configured grant”) resources. The T-TRP 170 further includes a memory 258 for storing information and data. The memory 258 stores instructions and data used, generated, or collected by the T-TRP 170. For example, the memory 258 could store software instructions or modules configured to implement some or all of the functionality and/or embodiments described herein and that are executed by the processor 260.

Although not illustrated, the processor 260 may form part of the transmitter 252 and/or part of the receiver 254. Also, although not illustrated, the processor 260 may implement the scheduler 253. Although not illustrated, the memory 258 may form part of the processor 260.

The processor 260, the scheduler 253, the processing components of the transmitter 252 and the processing components of the receiver 254 may each be implemented by the same, or different one of, one or more processors that are configured to execute instructions stored in a memory, e.g., in the memory 258. Alternatively, some or all of the processor 260, the scheduler 253, the processing components of the transmitter 252 and the processing components of the receiver 254 may be implemented using dedicated circuitry, such as a FPGA, a GPU or an ASIC.

Notably, the NT-TRP 172 is illustrated as a drone only as an example, the NT-TRP 172 may be implemented in any suitable non-terrestrial form. Also, the NT-TRP 172 may be known by other names in some implementations, such as a non-terrestrial node, a non-terrestrial network device, or a non-terrestrial base station. The NT-TRP 172 includes a transmitter 272 and a receiver 274 coupled to one or more antennas 280. Only one antenna 280 is illustrated. One, some, or all of the antennas may alternatively be panels. The transmitter 272 and the receiver 274 may be integrated as a transceiver. The NT-TRP 172 further includes a processor 276 for performing operations including those related to: preparing a transmission for downlink transmission to the ED 110; processing an uplink transmission received from the ED 110; preparing a transmission for backhaul transmission to T-TRP 170; and processing a transmission received over backhaul from the T-TRP 170. Processing operations related to preparing a transmission for downlink or backhaul transmission may include operations such as encoding, modulating, precoding (e.g., MIMO precoding), transmit beamforming and generating symbols for transmission. Processing operations related to processing received transmissions in the uplink or over backhaul may include operations such as receive beamforming, demodulating received signals and decoding received symbols. In some embodiments, the processor 276 implements the transmit beamforming and/or receive beamforming based on beam direction information (e.g., BAI) received from the T-TRP 170. In some embodiments, the processor 276 may generate signaling, e.g., to configure one or more parameters of the ED 110. In some embodiments, the NT-TRP 172 implements physical layer processing but does not implement higher layer functions such as functions at the medium access control (MAC) or radio link control (RLC) layer. As this is only an example, more generally, the NT-TRP 172 may implement higher layer functions in addition to physical layer processing.

The NT-TRP 172 further includes a memory 278 for storing information and data. Although not illustrated, the processor 276 may form part of the transmitter 272 and/or part of the receiver 274. Although not illustrated, the memory 278 may form part of the processor 276.

The processor 276, the processing components of the transmitter 272 and the processing components of the receiver 274 may each be implemented by the same or different one or more processors that are configured to execute instructions stored in a memory, e.g., in the memory 278. Alternatively, some or all of the processor 276, the processing components of the transmitter 272 and the processing components of the receiver 274 may be implemented using dedicated circuitry, such as a programmed FPGA, a GPU or an ASIC. In some embodiments, the NT-TRP 172 may actually be a plurality of NT-TRPs that are operating together to serve the ED 110, e.g., through coordinated multipoint transmissions.

The T-TRP 170, the NT-TRP 172, and/or the ED 110 may include other components, but these have been omitted for the sake of clarity.

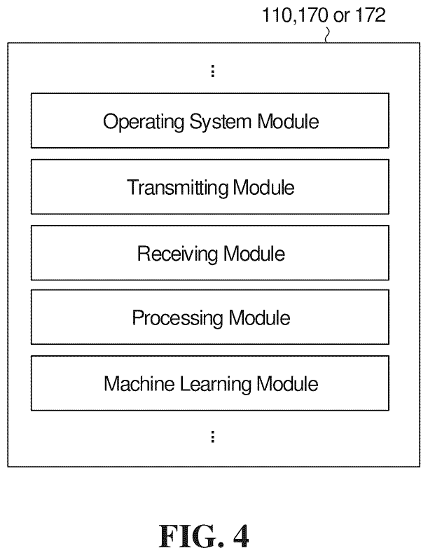

One or more steps of the embodiment methods provided herein may be performed by corresponding units or modules, according to FIG. 4. FIG. 4 illustrates units or modules in a device, such as in the ED 110, in the T-TRP 170 or in the NT-TRP 172. For example, a signal may be transmitted by a transmitting unit or by a transmitting module. A signal may be received by a receiving unit or by a receiving module. A signal may be processed by a processing unit or a processing module. Other steps may be performed by an artificial intelligence (AI) or machine learning (ML) module. The respective units or modules may be implemented using hardware, one or more components or devices that execute software, or a combination thereof. For instance, one or more of the units or modules may be an integrated circuit, such as a programmed FPGA, a GPU or an ASIC. It will be appreciated that where the modules are implemented using software for execution by a processor, for example, the modules may be retrieved by a processor, in whole or part as needed, individually or together for processing, in single or multiple instances, and that the modules themselves may include instructions for further deployment and instantiation.

Additional details regarding the Eds 110, the T-TRP 170 and the NT-TRP 172 are known to those of skill in the art. As such, these details are omitted here.

Having considered communications more generally above, attention will now turn to particular example embodiments.

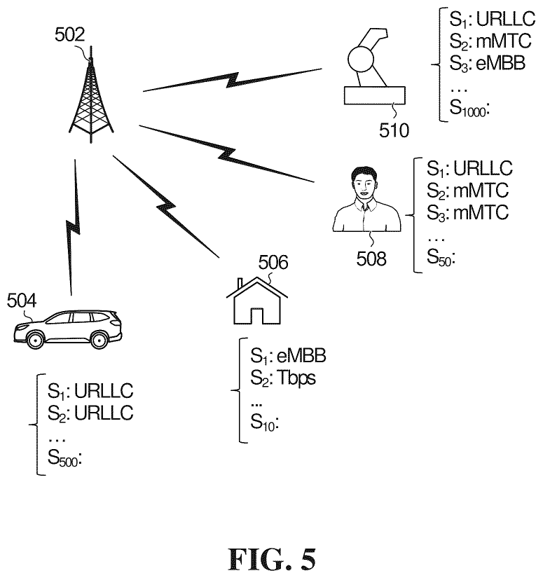

As referenced above, multiple services may converge or be integrated into one physical wireless link, and these services may have diverse key performance indicators (KPIs). FIG. 5 is a block diagram illustrating an example multi-service scenario, in which services integrated into one link may include any of URLLC, mMTC, eMBB, and Tbps services. In FIG. 5, communication devices include a network device 502, a vehicle-based device represented at 504, a home-based or other premises-based device represented at 506, a user device represented at 508, and an industrial or machine-based device represented at 510, each with example services as shown.

The present disclosure is not limited to these or any other types of devices or services. FIG. 5 is intended to provide one example scenario in which embodiments disclosed herein may be particularly useful. More generally, disclosed embodiments may be implemented, for example, in next-generation mobile and wireless network services, cloud and edge computing services, and sensing services. Some embodiments may be particularly useful for automated manufacturing systems in smart factories, and/or other intelligent vertical scenarios such as ports, delivery systems, and medical systems. These possible applications of embodiments are also illustrative and non-limiting examples.

A multi-service scenario, such as the scenario shown by way of example in FIG. 5, may be considered a form of intra-user equipment (UE) multiple access (MA). Intra-UE MA refers to concurrent transmissions of multiple services from one terminal device.

There are two primary types of channel coding, according to soft-output and hard-output decoder types.

Soft-output iteratively decoded codes, for example, include convolutional codes, turbo codes, low density parity check (LDPC) codes, product codes, and woven codes. These codes typically take a parallel and soft cancellation decoding approach, in which all parts of a code block are decoded simultaneously, and then soft decision information such as likelihood, probability, or LLR of all bits is exchanged across the whole code block before entering a next iteration. Such codes can also be jointly decoded. For example, after decoding two codes independently, soft information about shared bits (also referred to herein as coupled bits) can be exchanged (in an inter-code iteration) between two codes before their further decoding.

Hard-output successively decoded codes include polar codes, polarization-adjusted convolutional (PAC) codes, Reed-Muller (RM) codes, Bose-Chaudhuri-Hocquenghem (BCH) codes, and Reed-Solomon (RS) codes. These codes can implement a successive hard cancellation decoding approach, in which part of a code block in a received signal is decoded first, and then the hard decision of the decoded part is removed from the received signal before decoding a next part of the code block. These codes can also be decoded through joint successive cancellation. For example, after decoding one codeword, shared bits can be cancelled from another codeword, and then that other codeword can be decoded. Because codes belonging to any one type have more compatible decoders, they are more conveniently decoded together. Therefore, it may be preferable to use codes of the same type (i.e., soft or hard) for embodiments that are to enable or support joint decoding. However, it is also possible to use codes of different types in other embodiments.

Decoding type has a direct effect on design of a HARQ-less coding approach, and the present disclosure focuses primarily on embodiments that involve hard-output decoding.

Hard-output successive cancellation (SC) or successive cancellation list (SCL) decoding for polar, PAC, or RM codes performs sequential decisions on information bits. Once a code bit is decoded, the decision cannot be reverted. Some embodiments disclosed herein introduce new mechanisms for specific codes, such as polar codes with SC/SCL decoding, to support a further decoding attempt after a decoding failure, without requesting retransmission. This type of approach is also referenced herein as HARQ-less coding. Embodiments herein may also support self-decodable and joint decoding features, such that individual payloads, which may correspond to respective different services for example, can be self-decoded and also support joint decoding to further enhance performance.

A joint FEC includes multiple coupled codewords. Either bit-by-bit hard decision decoding or block-by-block hard decision decoding of each codeword may be supported. Both self-decoding of a codeword and enhanced joint decoding of multiple codewords is enabled in some embodiments by coupling the codewords with shared payload bits, which may be or include information bits, systematic bits, code bits, or possibly a combination of different types of bits. Such shared payload bits may be referred to, herein or elsewhere, as shared bits, common bits, coupled bits, coupling bits, or by some other name.

Placement of shared or common payload bits may affect either or both of (a) the time at which a bit is decoded and (b) the reliability of decoding a bit. As an example and without loss of generality, suppose that there are two codewords, including a Codeword 1 (for URLLC data, for example) that is to be decoded with higher priority, and a Codeword 2 (for eMBB data, for example) that is to be decoded with lower priority. In this example, based on its higher priority, joint decoding should be supported for Codeword 1, to perform a second decoding attempt with the help of the lower-priority Codeword 2. No HARQ or other retransmission is involved in the second decoding attempt.

For completeness, with coupled codewords as in this example, joint decoding could be used in a second decoding attempt for Codeword 2, but this likely would not be a common application of joint decoding for a second decoding attempt. It is expected that a joint decoding attempt would be made for a codeword with a higher decoding priority, which is Codeword 1 in this example, rather than for a codeword with a lower decoding priority.

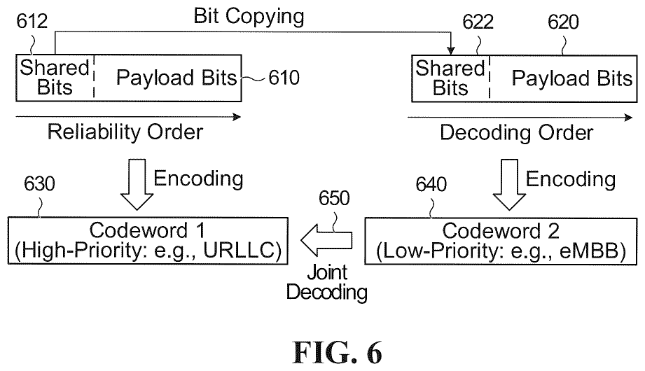

FIG. 6 is a block diagram illustrating encoding and decoding according to an embodiment. Payload bits are shown at 610, 620, and may be associated with different services such as URLLC and eMBB in the illustrated example. The payload bits 610, with a higher decoding priority, include shared bits 612 that are also copied for encoding with the payload bits 620. Codeword 1 and Codeword 2 are shown at 630, 640, respectively, and joint decoding is shown at 650.

The example shown in FIG. 6 is illustrative of an embodiment in which encoding involves copying a portion or subset 612 of the payload bits 610 for Codeword 1 (630) to the beginning at 622 of payload bits 620 for Codeword 2 (640). The bit copying direction in FIG. 6, from 612 to 622, is intended to represent that the shared bits 612, which are a subset of the payload bits 610, are copied into the payload bits 620, by prepending the shared bits at the beginning of the payload bits 620 at 622 in this example. The number of payload bits for encoding to generate Codeword 2 is thereby increased.

The encoding for payload bits 610 in FIG. 6 provides different reliabilities, and an arrangement of the payload bits 610 in increasing order of reliability is shown. Encoding is performed on the payload bits 610 to generate Codeword 1 (630). The increased payload bits 620, which include the shared bits 622 copied from the payload bits 610 and may also be referred to as a combined payload for example, are shown in decoding order in FIG. 6. Decoding order refers to the order in which coded bits are to be decoded at a receiver or receive side or a decoder or decode side. Encoding is performed on the increased payload bits 620 to generate Codeword 2 (640).

Turning now to decoding, in an embodiment self-decoding to decode Codeword 1 (630) is first attempted using only received symbols of Codeword 1. If the self-decoding fails, then decoding proceeds to joint-decoding, in which the payload bits 620 are decoded from Codeword 2 (640). When all shared bits 622 are decoded from Codeword 2, a second attempt is made to decode the payload bits 610 from Codeword 1, treating the corresponding shared bits 612 as known. There is no need to decode these shared bits 612 again, because they have already been decoded from Codeword 2. Decoding of Codeword 2 may be halted or paused when the shared bits 622 have been decoded, while the second attempt to decode Codeword 1 is proceeding. After all payload bits 610 have been decoded from Codeword 1, processing may return to complete the decoding of Codeword 2.

Polar codes are discussed below to provide a more detailed example. However, embodiments are not in any way limited to polar codes. Features disclosed herein may also or instead be implemented in conjunction with other types of codes that involve hard-decision decoding.

For polar codes, payload bits are mapped to information bit indices, which are in turn associated with subchannels. Subchannels are also referred to as bit channels. In polar coding, frozen bits are also mapped to other bit indices and subchannels or bit channels. Each bit index or subchannel is associated with a reliability metric. In 5G standards, for example, reliability is specified in a table by a reliability ordered sequence of indices and corresponding reliability weights. Decoding order for polar codes follows bit index order, because an SC/SCL decoder sequentially decodes all frozen bits and information bits by bit index order.

Any of various encoding features or parameters may be relevant to embodiments disclosed herein. Illustrative examples are provided at least below, and any of those examples may be implemented, individually or in any combinations.

As a first example, an order of selection of code rates and lengths for different types of payloads may be specified or supported. In a multi-service scenario, selection order may be based on the services that are associated with payload types. Selection of code rates and lengths, by modulation and coding scheme (MCS) index or other identifier for example, may be made for URLLC and/or mMTC payloads after selection of code rate(s) and length(s) for eMBB code(s) for coding eMBB data. MCS index selection for the URLLC/mMTC code(s) in this example may take a selected eMBB MCS index as an input, or otherwise take the selected eMBB MCS index into account, so that MCS index selection for the URLLC/mMTC code(s) in this example is based on the selected eMBB MCS index selection. More generally, selection of code rate and length for coding of one type of payload may be based, at least in part, on a code rate and length that is selected for coding another type of payload.

According to another example, relative code length of codes for different types of payloads are specified or supported. Considering again a URLLC/mMTC and eMBB scenario, URLLC/mMTC code(s) shorter than eMBB code(s), and/or equivalently eMBB code(s) longer than URLLC/mMTC code(s), may be specified or supported. Therefore, when a URLLC/mMTC payload or codeword is to be coupled to an eMBB payload or codeword, an eMBB code that is longer, with more code bits, is to be selected for eMBB coding. More generally, in some embodiments a code selected for encoding a payload from which shared bits are copied is shorter than, or in other words has a shorter code length or fewer code bits than, a code selected for encoding a payload into which shared bits are copied. Stated another way, in some embodiments a code selected for encoding a payload into which shared bits are copied is longer than, or in other words has a longer code length or more code bits than, a code selected for encoding a payload from which shared bits are copied.

Another example of an encoding feature that may be specified or supported in some embodiments is relative code rates of codes for different types of payloads. In a URLLC/mMTC and eMBB scenario, URLLC/mMTC code rate(s) lower than the code rate(s) of the eMBB code(s) may be preferred. For example, when a URLLC/mMTC payload or codeword is to be coupled to an eMBB payload or codeword, an eMBB code that has a higher code rate is to be selected for eMBB coding. More generally, in some embodiments a code selected for encoding a payload from which shared bits are copied may have a lower code rate than a code selected for encoding a payload into which shared bits are copied, or equivalently a code selected for encoding a payload into which shared bits are copied may have a higher code rate than a code selected for encoding a payload from which shared bits are copied.

A further example of an encoding feature that may be specified or supported relates to shared or common bit selection and positioning. Shared or common bits in one payload may be selected or otherwise determined, and placed or positioned in another payload, based on any of various criteria, such as reliability, decoding order, or both. Reliability and decoding order are referenced herein as illustrative and non-limiting examples. Embodiments are not in any way restricted to determining which bits of one payload are the common or shared bits to be copied and combined with bits of another payload. Other examples are provided elsewhere herein.

In a URLLC-eMBB scenario in which shared information bits are to be copied from a URLLC payload into an eMBB payload, the shared bits in the URLLC payload may be the least reliable information bits; and the shared bits are placed in the eMBB payload as the first decoded information bits, with smallest bit indices in the eMBB payload. URLLC is used here as an example, but more generally any other latency-sensitive service may benefit from shared bit selection or determination based on either or both of reliability and decoding order.

Considering an mMTC-eMBB scenario in which shared information bits are to be copied from an mMTC payload into an eMBB payload, the shared bits in the mMTC payload may be the least reliable information bits; and the shared bits are also placed in the eMBB payload at the least reliable bit positions. mMTC is used here as an example, but more generally any other delay-tolerant service may benefit from shared bit selection or determination based on reliability.

These information bit copying examples, for URLLC-eMBB and mMTC-eMBB scenarios illustrate that shared bits may be selected or otherwise determined, and placed or positioned in a different payload, based on both reliability and decoding order as in the URLLC-eMBB scenario, or based on reliability as in the mMTC-eMBB scenario. In another embodiment, shared bits may be selected or otherwise determined and/or placed in another payload based on decoding order.

Regarding reliability, information bits in positions that have lowest reliability are less likely to be decoded correctly, and therefore copying those information bits as shared bits into a different payload may provide the most benefit from a joint, second decoding attempt. Copying such shared information bits into even the least reliable bit positions in another payload as in the mMTC-eMBB scenario above provides a benefit in that a second, joint decoding attempt may be made if a first, self-decoding attempt fails. Copying shared bits from least reliable information bit positions in a first payload into most reliable information bit positions in a second payload may provide greater benefit to the first payload, but at a cost of other information bits in the second payload no longer being mapped to its most reliable information bits position, into which the shared bits from the first payload are copied. While, in some embodiments, it may be desirable that all of the shared bits in the first payload are the least reliable information bits, in other embodiments, it may also be possible yet still beneficial that fewer than all of the shared bits in the first payload are the least reliable information bits. Thus, one or more of the shared bits may be of greater reliability than one or more information bits that are not shared bits. Similarly, while it may be desirable that all of the shared bits are copied to the least reliable information bit positions of the second payload, in other embodiments, it may also be possible yet still beneficial that fewer than all of the shared bits are copied to the least reliable information bit positions of the second payload. Thus, one or more of the shared bits may be copied to information bit position(s) of greater reliability than one or more information bit positions that do not correspond to shared bits in the second payload.

Regarding decoding order, for a delay-sensitive payload such as a URLLC payload, decoding time or latency is important. For such payloads, it may be preferred to copy shared bits into information bit positions in another payload that are decoded first. In this way, in the event of a decoding failure on a first, self-decoding attempt for the delay-sensitive payload, the additional decoding latency added by the second, joint-decoding attempt can be minimized. The shared bits in the other payload are decoded first and become available for use in the second decoding attempt for the delay-sensitive payload sooner than would be the case if the shared bits were to be copied into later-decoded bit position in the other payload. This decoding-order based placement of shared bits also comes at a cost to the other payload into which the shared bits are copied, in terms of delay in decoding the other bits of the other payload because the shared bits are decoded before those other bits. However, the other payload may be more delay-tolerant (less delay-sensitive) than the payload from which the shared bits were copied. While, in some embodiments, it may be desirable that all of the shared bits are copied to the first decoded information bit positions of the second payload, in other embodiments, it may also be possible yet still beneficial that fewer than all of the shared bits are copied to the first decoded information bit positions of the second payload. Thus, one or more of the shared bits may be copied to information bit position(s) that are decoded later than one or more information bit positions that do not correspond to shared bits in the second payload.

Shared bits enable or support decoding features that may help improve performance. Considering again a URLLC-eMBB scenario, if URLLC self-decoding, which may also be referred to as local decoding, is successful then the corresponding shared bits that were copied into an eMBB payload may be set to the URLLC-decoded values and treated as parity check-frozen (PC-frozen) or known frozen bits. In this way, eMBB performance can be enhanced. Otherwise, if the URLLC local decoding fails, then there is still a good chance that the smallest index information bits will be correctly decoded from an eMBB codeword, and the corresponding shared bits in the URLLC payload can be PC-frozen to help URLLC decoding.

These example encoding and decoding features are illustrative of distinguishing features disclosed herein, which may help provide multiple services with both unequal error protection capability and local decodability.

Examples of encoding features or parameters that may be specified or supported in some embodiments are provided at least above. Decoding features or parameters may also or instead be specified or supported, and illustrative examples of such decoding features or parameters are provided at least below. Any of these examples may be implemented, individually or in any combinations.

Regarding a first decoding attempt, higher priority payloads may be decoded first, and then lower priority payloads may then be decoded if the higher priority payloads are correctly decoded. In a URLLC-eMBB polar code scenario as an example, URLLC decoding may be higher priority and involve decoding shorter polar codes with shorter codewords, and a first decoding attempt to decode all bits in one or more short polar codes (URLLC) before decoding all bits of one or more longer polar codes with longer codewords (eMBB). This is one example of a decoding order that may be specified or supported.

A second decoding attempt that may be specified or supported for a failure of the higher priority payload decoding involves an attempt to jointly decode the higher priority payload(s) using shared bits correctly decoded in lower priority decoding. In the above URLLC-eMBB example, if the URLLC decoding fails, then the second decoding attempt that is to be performed may involve decoding the shared bits in a longer polar code (eMBB), setting the shared bits in one or more shorter polar codes (URLLC) as PC-frozen bits, decoding the shorter polar code(s), and proceeding with decoding of the longer polar code (eMBB).

Although it may be expected that this example of a second decoding attempt is likely to be more common in order to provide enhanced protection for higher priority payloads (URLLC in this example), another second decoding attempt that may also be specified or supported involves an attempt to jointly decode lower priority payload(s) using shared bits that have been correctly decoded in higher priority decoding. In the example URLLC-eMBB scenario, if eMBB decoding fails, a second decoding attempt may be performed for decoding an eMBB payload. This is another example of joint decoding in a second decoding attempt, and may involve decoding shared bits from one or more shorter polar codes (URLLC), setting the shared bits in one or more longer polar codes (eMBB) as PC-frozen bits, decoding the longer polar code(s) (eMBB), and proceeding with decoding of the shorter polar code(s) (URLLC). In this example, another possible variation is to complete URLLC decoding first, and then perform first and (if necessary) second eMBB decoding attempts.

URLLC is merely intended to be illustrative of a service having a higher decoding priority. mMTC is another example of a service that may have higher decoding priority than eMBB. Embodiments may be implemented, for example, in any of various multi-service scenarios, such as a URLLC-eMBB scenario, an mMTC-eMBB scenario, or a three-service scenario for URLLC, mMTC, and eMBB. In the latter example, an mMTC codeword can be treated as part of a joint codeword together with URLLC and eMBB codewords.

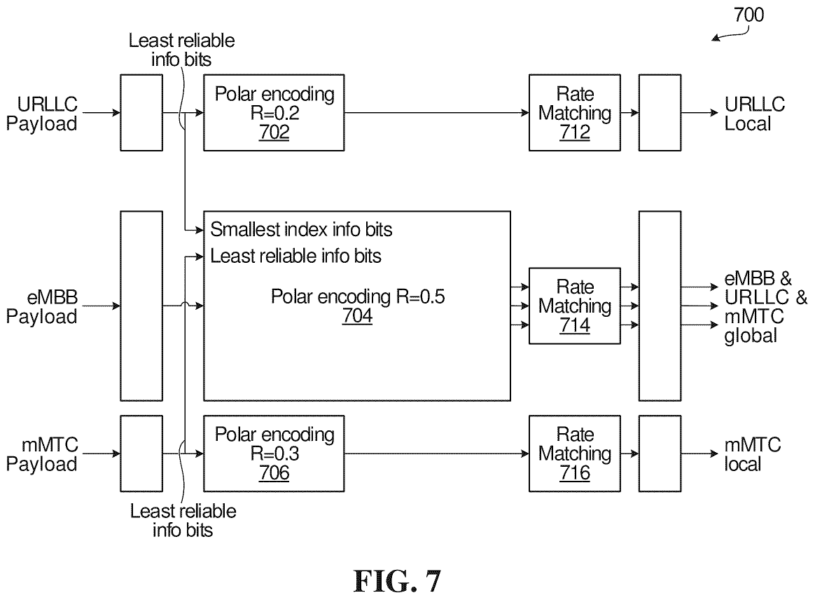

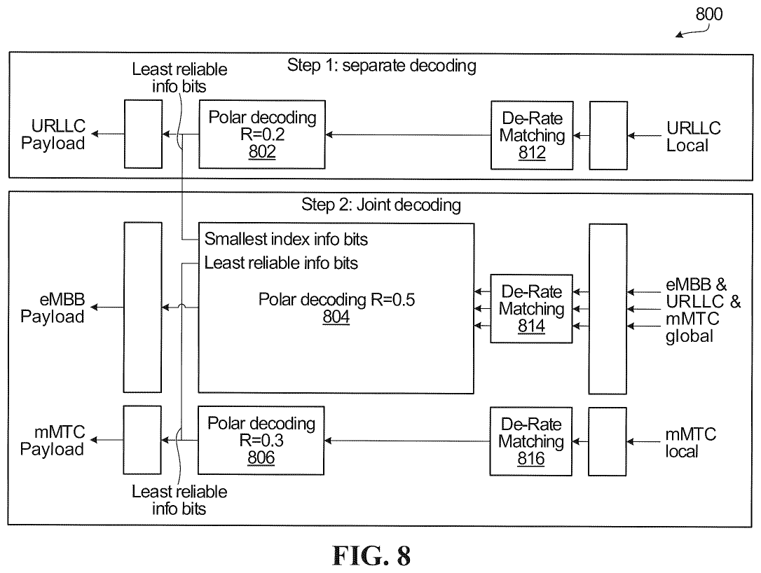

FIG. 7 is a block diagram illustrating an example of encoding according to an embodiment, and FIG. 8 is a block diagram illustrating an example of decoding according to an embodiment. The examples in FIGS. 7 and 8 are illustrative of a three-service scenario in which individual payloads associated with three services (URLLC, eMBB and mMTC) are coupled into a joint FEC. Variations to the examples in FIGS. 7 and 8, for coupling fewer or more than the three example services, and/or different example services, would be apparent to persons of skill in the art, and are not described in detail herein to avoid unnecessary repetition.

With reference first to the encoding example 700 in FIG. 7, polar encoding is shown at 702, 704, 706 as one example of encoding that may be applied to individual payloads. Shared bits are copied from the URLLC individual payload and the mMTC individual payload into the eMBB individual payload. The shared bits are the least reliable bits from the URLLC individual payload and the mMTC individual payload, the shared bits from the URLLC individual payload are copied into the smallest index bit positions of the eMBB individual payload, and the shared bits from the mMTC individual payload are copied into the least reliable bit positions of the eMBB individual payload. This is one example only, and other embodiments in which shared bit copying is based on one or more other parameters, such as decoding order, in addition to or instead of reliability, are possible. The code rates R illustrated in FIG. 7 are also examples, and may be the same or different in other embodiments.

Rate matching, which may involve puncturing and/or shortening for example, may be provided in some embodiments, and is illustrated at 712, 714, and 716 for the URLLC, eMBB, and mMTC coding in FIG. 7. This is intended to be illustrative of other features or operations, which may or may not include rate matching, that may be implemented in conjunction with encoding as disclosed herein.

In the example shown, the URLLC and mMTC “local” codewords are self-decodable, and the eMBB codeword is labelled as a “global” codeword to indicate that it is generated based on a payload that includes not only eMBB payload bits, but also shared bits that include respective subsets of the URLLC individual payload and the mMTC individual payload. The two local codewords and the global codeword may be considered and referred to as a joint codeword.

The decoding example 800 in FIG. 8 illustrates decoding counterparts of encoding features that are shown in FIG. 7. Optional de-rate matching is shown at 812, 814, 816 as an example of decoding features that may be provided in some embodiments, and polar decoding is shown at 802, 804, 806.

As an example, separate decoding of a URLLC individual payload is shown as a first decoding step. A first decoding step or attempt may also or instead include separate decoding for mMTC and/or eMBB. Joint decoding in step 2 is intended to illustrate a second decoding attempt as disclosed herein. In the example shown, the joint decoding assists at least URLLC decoding in the event of a URLLC decoding failure. The shared, least reliable, URLLC payload bits may be successfully decoded at 804 and used in decoding the remaining URLLC payload bits at 802. In order to avoid further congestion in the drawing, the shared bits decoded at 804 are shown as being output from 804 as part of a decoded URLLC payload, but those shared bits decoded at 804 may also or instead be used to set the shared bits to PC-frozen at 802 to assist in decoding a received URLLC local codeword at 802.

Shared mMTC bits are similarly shown in FIG. 8, and may be used to assist in decoding the mMTC payload from a received mMTC local codeword at 806. Joint decoding for mMTC may be a second decoding attempt if mMTC separate decoding fails.

Shared bits are shown in FIG. 8 as decoding outputs from 804, but in other embodiments shared bits may be used for joint decoding of a received global codeword. Successfully decoded shared bits from 802 and/or 806 may be used to set the shared bits to PC-frozen at 804.

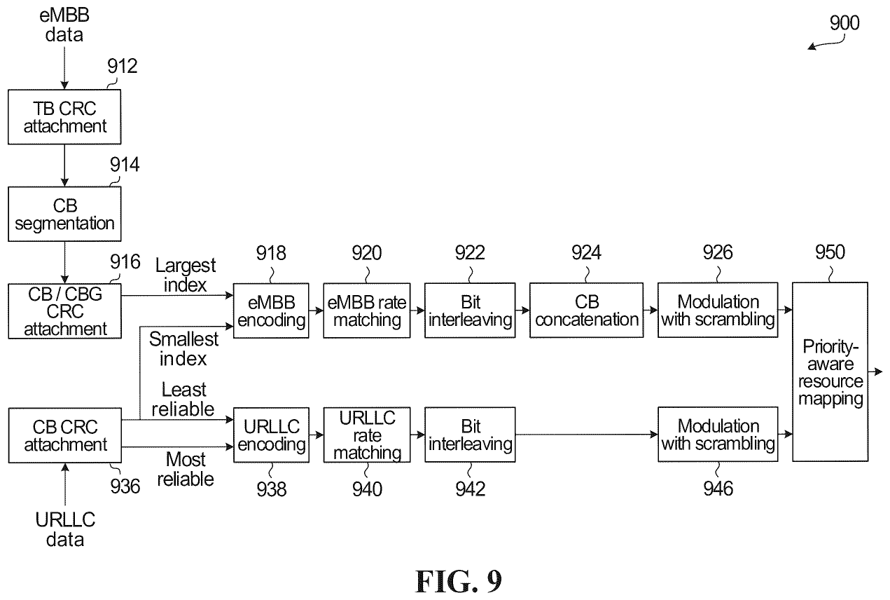

FIG. 9 is a block diagram of an example encoding chain according to an embodiment. The example encoding chain 900 is for a URLLC-eMBB scenario, but as noted elsewhere herein other embodiments are possible.

The features or functions shown in FIG. 9 include transport block (TB) cyclic redundancy check (CRC) attachment for eMBB data at 912, code block (CB) segmentation for the eMBB data at 914, CB or CB group (CBG) CRC attachment for the eMBB data at 916, CB CRC attachment for the URLLC data at 936, encoding at 918, 938 for each of the eMBB data and the URLLC data, rate matching for each of the eMBB data and the URLLC data at 920, 940, bit interleaving for each of the eMBB data and the URLLC data at 922, 942, CB concatenation for the eMBB data at 924, modulation with scrambling for each of the eMBB data and the URLLC data at 926, 946, and priority-aware resource mapping at 950. Other embodiments may include additional, fewer, or different elements interconnected in a similar or different way.

Encoding chain features or functions may be implemented in any of various ways, such as in hardware, firmware, or one or more components that execute software. The present disclosure is not limited to any specific type of implementation, and implementation details may vary between different devices, for example.

Many of the features in FIG. 9 may be provided or supported according to conventional coding techniques. The example encoding chain 900, however, embodies several distinctions. For example, in some embodiments URLLC data is limited to be within one CB, and therefore TB CRC attachment, CB segmentation, and CB concatenation are shown at 912, 914, 924, respectively, only for eMBB data. Shared bit copying to couple the eMBB and URLLC data and codewords together at 918, 938 is a further distinction. The priority-aware resource mapping at 950 preferably helps to ensure reliable and low-latency reception of URLLC symbols, for example by mapping URLLC data to frequency (subcarrier) and/or spatial (layer) resources that have better channel quality, and/or to time slots that are transmitted earlier.

As an example, bits of the eMBB data in a CB after CB segmentation and CRC attachment are denoted by e₀, e₁, . . . , e_{K-1}, where K is the number of payload bits. For the sake of simplicity, CB number is omitted in this notation. For URLLC, bits after CRC attachment are denoted by u₀, u₁, . . . , u_{K′-1}, where K′is the number of payload bits. A subset of the K′URLLC payload bits, including K″ bits so that the subset is of size K″, are copied and attached to the beginning of eMBB payload. This subset is also referred to herein as shared bits, common bits, or coupled bits. The new eMBB bits for encoding become u₀, u₁, . . . , u_{K′-1}, e₀, e₁, . . . , e_{K-1}, which may be denoted as c₀, c₁, . . . , c_{K″+K-1}.

The new eMBB bits c₀, c₁, . . . , c_{K″+K-1} are mapped to information bit positions in an eMBB code by ascending bit index order in some embodiments, as an example of decoding order-based copying of shared payload bits from one payload into another payload. The URLLC bits u₀, u₁, . . . , u_{K′-1} are mapped to information bit positions in a URLLC code by ascending reliability order in some embodiments, as an example of selecting or determining the shared payload bits that are to be copied based on reliability. The new eMBB payload including c₀, c₁, . . . , c_{K″+K-1} and the URLLC payload including u₀, u₁, . . . , u_{K′-1} are encoded, at 918, 938, respectively, according to general procedures of polar encoding for example.

In vertical scenarios such as in industrial applications, for example, there are likely to be services with different traffic that has different payload sizes and different QoS requirements. Control instructions and data generated by different types of sensors or monitors of a single device are examples of different traffic that may involve different services. A robot arm, for example, may communicate with a network device such as a base station, and support URLLC, eMBB and mMTC services. In one possible implementation to illustrate how these services might be used, video stream data transmissions from a camera on the robot art may belong to an eMBB service, signaling for controlling each of one or more joints of the robot arm may belong to a URLLC service, and delay-insensitive sensing or monitoring data reporting may belong to an mMTC service. Such differences may be addressed by proper signaling in accordance with embodiments herein.

With joint coding as proposed herein, it may be possible to boost coding gain of smaller payload data, and help support fast decoding of such smaller payload data, which may have tighter QoS requirements or otherwise have higher decoding priority than other data. Signaling to indicate one or more joint coding parameters may be or include, for example, downlink control information (DCI) with an indication of the joint coding parameter(s). Examples of joint coding parameters include coding structure, data partition, and priority order for individual payloads. Any one or more of these joint coding parameters, and/or others, may be indicated in signaling.

Without loss of generality, suppose that there are three services, including S₁=URLLC, S₂=eMBB. and S₃=mMTC. Signaling examples for such an embodiment are provided below. It should be appreciated, however, that these examples are intended solely for illustrative purposes, and the present disclosure is not in any way limited to three-service scenarios or to these particular signaling examples.

In an embodiment, signaling indicates a coding mode. Coding mode may specify whether only separate coding or joint coding is to be used. If joint coding is to be used, then coding mode may further specify how many services, and which services, are to be jointly encoded to support joint decoding. In the three-service scenario referenced above, the maximum supported joint coding is for three services, and a coding mode indication or specification may be summarized as shown below in Table 1.

TABLE 1
Specifying Coding Modes
Coding mode indicators

| Joint coding Indicator | 0 = separate encoding, |
|---|---|
| (1 bit) | 1 = joint encoding |
| Number indicator (2 bits) | {0, 1, 2, 3} |
| Combination indicator (2 bits) | S1 & S2 |
| | S1 & S3 |
| | S2 & S3 |
| | S1 & S2 & S3 |

Table 1 is an example, and variations are possible. For instance, if the Number indicator indicates the total number of services, then the Combination indicator need not necessarily be included in signaling because the Number indicator provides an implicit indicator that data for all services is to be jointly encoded. The Number indicator might not be used in all embodiments, because the Combination indicator may provide an implicit indicator of the number of services for which data is to be jointly encoded. Other embodiments may be implemented these and/or other variations in specifying coding modes or coding parameters.

Signaling may also or instead be used to indicate MCS, by MCS index for example, for all services. There are several options.

One MCS option for joint coding is to use the same MCS for all services. For example, an MCS table for one service, such as URLLC or another service that has high decoding priority for example, may be used for joint coding. Another embodiment involves defining a new MCS table for joint coding that uses a different (smaller for example) modulation order and different (lower for example) target code rate than specified in an MCS table for one of the services. For example, an MCS table for joint coding that uses a smaller modulation order and lower target code rate than specified in an eMBB MCS table sacrifices some eMBB spectral efficiency to help improve URLLC performance.

For joint coding, the same modulation order may be used for all services, but different code rates may be used for each service. For example, it is possible to define a new MCS table, where each MCS index is associated with one modulation order and multiple code rates. Multiple MCS tables may be used to cover cases with different numbers of jointly encoded services, with each MCS table corresponding to a respective number of jointly encoded services. Depending on the Number indicator in Table 1 above, for example, one of the following tables, Table 2 and Table 3, may be selected.

TABLE 2
MCS Table for Two Jointly Encoded Services
MCS table for two jointly encoded services

| MCS | Modulation | Target code | Target code |
|---|---|---|---|
| index | order | rate 1 | rate 2 |
| 0 | M0 | R1 | R2 |
| . . . | . . . | . . . | . . . |

TABLE 3
MCS Table for Three Jointly Encoded Services
MCS table for three jointly encoded services

| | Modulation | Target code | Target code | Target code |
|---|---|---|---|---|
| MCS index | order | rate 1 | rate 2 | rate 3 |
| 0 | M0 | R1 | R2 | R3 |
| . . . | . . . | . . . | . . . | . . . |

Priority order for each service Si is another example of a joint coding parameter that may be indicated in signaling. Such priority may be indicated by a priority metric or a priority order index for each service, for example. Priority order may affect priority-aware resource mapping in some embodiments, and/or the services or payloads from and to which shared data bits are copied. In an embodiment, priority is denoted by a positive number {1, 2, 3 . . . }, with the smaller (or larger) number indicating higher priority.

Another joint coding parameter that may be used or supported in some embodiments is coding structure. One aspect of coding structure is the type of code that is to be used for the data associated with each service, which may be denoted in any of various ways, such as by {S1=RM, S2=PAC, S3=Polar . . . }. Bit selection order is another possible aspect of coding structure, and may be an order in which, or a criterion or criteria based on which, shared bits are to be selected for copying from and/or placed relative to payload bits for a different service. Order may be denoted by {reliability, bit index, decoding order}, for example. A further aspect of coding structure is the “target” service to which shared bits are copied to couple one service or payload to another. The target service may be indicated by an index or other identifier, as in the above example of S1, S2, S3, and a zero value may indicate that no bits are to be copied as shared bits from a particular service to another service. A service for which no target service is indicated may be a target service for another service. In other words, a service that does not itself have a target service may act as a target service and in effect attach bits from one or more other services for joint coding.

Partition is another possible joint coding parameter, and relates to how to partition payload bits in each service, or in other words how many bits or how much of a payload is to be shared. An integer number of bits, or a fraction or other relative proportion may be used to indicate partition.

Table 4 below summarizes joint coding parameters that may be used and indicated in signaling in some embodiments, based on the examples above.

TABLE 4
Joint Coding Parameters
Joint coding parameters

| Service ID | 1 (URLLC) | 2 (eMBB) | 3 (mMTC) |
|---|---|---|---|
| Priority order | 1 | 2 | 3 |
| Code type | RM | Polar | PAC |
| Target service ID(s) for | 2 | ∅ | 2 |
| coupling | | | |
| Bit selection order | From: | ∅ | From: |
| | reliability | | reliability |
| | To: bit | | To: |
| | index | | reliability |
| Partition (proportion of | ¼ | 0 | ⅛ |
| shared bits) | | | |

Table 4, like other examples herein, is intended to be non-limiting. Other embodiments may support any one or more of these joint coding parameters, and/or different joint coding parameters. The above examples of parameters are not exhaustive, and others include: number of available resource elements (REs) for each service; number of layers (MIMO group) for each service; and mapping method from service to corresponding layer(s), such as frequency-time or time-frequency. These additional examples are also illustrative, and general embodiments may use, and/or indicate in signaling, any one or more of various joint coding parameters, which may include but are not limited to the particular examples provided herein.

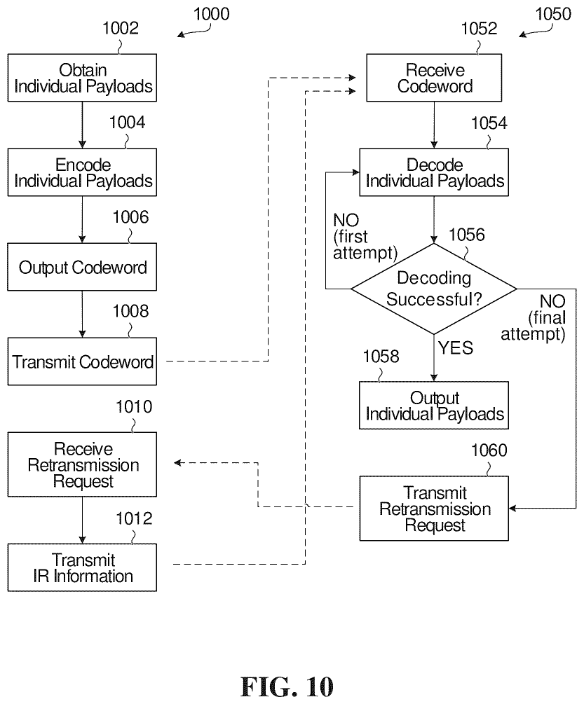

Various aspects of the present disclosure are described above and shown in the drawings by way of example. FIG. 10 is a flow diagram illustrating more general example methods according to embodiments. At the left, 1000 in FIG. 10 illustrates operations or features that may be provided or supported at an encoder or transmitter-side device, and at the right, 1050 illustrates operations or features that may be provided or supported at a decoder or receiver-side device. For ease of reference, in the following description of FIG. 10, a device at which encoding and/or transmitting features may be implemented or supported is called a first communication device, and a device at which decoding and/or receiving features may be implemented or supported is called a second communication device. Embodiments may involve either or both of such devices.

With reference first to 1000, from a transmitting device perspective the transmitting at 1008 is intended to represent transmitting a codeword by a first communication device to a second communication device in a wireless communication network. The codeword is or includes encoded blocks generated by error correction encoding respective individual payloads. The encoded blocks include a self-decodable encoded block that is generated by error correction encoding a first individual payload, and another encoded block generated by error correction encoding a second individual payload with which a portion of the first individual payload is combined for error correction encoding. The self-decodable encoded block is decodable independently of the other encoded block, and is also decodable jointly with the other encoded block.

FIG. 10 also illustrates operations that may be involved in generating a codeword. At 1002, FIG. 10 illustrates obtaining individual payloads, including at least a first individual payload and a second individual payload, which may be or include data from different devices and/or data associated with different services, for example. Obtaining the payloads at 1002 may involve, for example, collecting or otherwise receiving data outputs from one or more devices and/or services, or accessing payload data in a memory.

1004 is intended to illustrate error correction encoding of each of the individual payloads. In an embodiment, this involves error correction encoding the first individual payload to generate a self-decodable encoded block, and error correction encoding the second individual payload with which a portion of the first individual payload is combined for error correction encoding, to generate another encoded block.

As shown at 1006, a method may also involve outputting a codeword that includes the self-decodable encoded block and the other encoded block generated at 1004. The codeword may be output for storage to memory, and/or transmission at 1008 for example.

In some embodiments, a method may involve obtaining as shown at 1002, encoding as shown at 1004, and outputting as shown at 1006. Other embodiments may involve transmitting a codeword as shown at 1008. These embodiments are not mutually exclusive, and methods may involve obtaining and encoding individual payloads as shown at 1002, 1004, and also transmitting a codeword as shown at 1006.

As disclosed herein, a self-decodable encoded block is decodable independently of one or more other encoded blocks, and is also decodable jointly with the other encoded block(s). In the context of the above example of a self-decodable encoded block and another encoded block generated by error correction encoding of a first individual payload and a second individual payload with which a portion of the first individual payload is combined, the self-decodable encoded block is decodable independently of the other encoded block and is also decodable jointly with the other encoded block.

The portion of one individual payload (the first individual payload in the above examples) that is combined with another individual payload (the second individual payload in the above examples) links or couples those payloads and the encoded blocks together, to provide or support joint decodability. Joint decodability of a self-decodable encoded block may provide or enable any of various other features disclosed herein. For example, the fact that a self-decodable encoded block is further decodable jointly with one or more of the other encoded blocks of a codeword may enable joint decoding of the one or more of the other encoded blocks based on successful decoding of the self-decodable encoded block independently of the other encoded blocks. In the context of the above example, the self-decodable encoded block further being decodable jointly with the other encoded block may enable joint decoding of the self-decodable encoded block after a decoding failure in decoding the self-decodable encoded block independently of the other encoded block.

The portion of an individual payload that is to be combined with another individual payload may be selected, identified, or otherwise determined based on any of various criteria. Several examples are provided herein, and may be generalized as the portion of one (the first in the above example) individual payload being determined for combining with another (the second in the above example) individual payload based on an ordering of bits of the one (first) individual payload.

Such an ordering or ranking of bits may be or include an ordering based on a property of the bits of the first individual payload. This property may be or include any one or more of decoding reliability, decoding order, bit position index, and a reliability weight.

Decoding reliability is discussed at least above as an illustrative example. Common or shared bits that are to be copied from one (the first above) individual payload to another (the second above) individual payload may be determined based on decoding reliability of information bit positions in the one (first) individual payload, for example. It should be noted that reliability need not itself be explicitly specified, configured, or signaled. For example, decoding reliability may be mapped to an index or an integer by a table or a formula, to denote reliability without explicitly referring to reliability. Determining the portion of one (the first above) individual payload for combining with another (the second above) individual payload for error correction encoding based on decoding reliability may involve determining that the portion is to include information bits in the one (first) individual payload that have the lowest decoding reliability, for example. A reliability-ordered sequence is one example of a decoding reliability order based upon which a portion or shared bits of an individual payload may be determined.

Decoding order is referenced above primarily in the context of determining where shared bits in one individual payload are to be placed for combining with another individual payload. However, decoding order may also or instead be considered in determining the shared bits, which as also referenced herein as the portion of one (the first above) individual payload for combining with another (the second above) individual payload for error correction encoding. For example, it may be beneficial to determine that the portion or shared bits in one (the first above) individual payload for combining with another (the second above) individual payload for error correction encoding should include bit that will be decoded from the self-decodable encoded block first, so that it will be known earlier in the decoding process whether decoding of the portion or shared bits is successful.

Bit position index is another example of a property upon which ordering of information bits in an individual payload and determining a portion for combining with another individual payload may be based. The portion or shared bits may be selected or otherwise determined as the first X bits (lowest bit position indices) or the last Y bits (highest bit position indices) in an individual payload, for example.

The portion or shared bits to be copied from an individual payload may also or instead be determined based on ordering by a reliability weight. A reliability weight value Win 3GPP TS 38.212 version 15.2.0 is one example of a reliability weight based upon which a portion or shared bits of an individual payload may be determined.

Reliability weight is also an example of a calculated weight property based upon which information bit positions in an individual payload may be ordered for determination of the portion or shared bits that are to be copied and combined with information bits in another individual payload. Ordering of bits in an individual payload may also or instead be based on one or more other types of weight values. Polarization weight, as disclosed in WO2018/019044 is one example of another type of weight value on which ordering of bits in an individual payload may be based.

These example properties are not necessarily non-overlapping or mutually exclusive. For example, a reliability-ordered sequence in 3GPP TS 38.212 version 15.2.0 specifies reliability order in terms of information bit positions, and therefore determining the portion or shared bits in one (the first above) individual payload that are to be combined with bits in another (the second above) individual payload may be considered a form of determining the portion or shared bits based on ordering according to decoding reliability and/or according to bit position index. It should also be appreciated that multiple properties may be used in ordering information bits for selection as the portion or shared bits to be copied from one (the first above) individual payload and combined with bits in another (the second above) individual payload.

The examples above refer to determining the portion or shared bits to be copied from one (the first above) individual payload and combined with bits in another (the second above) individual payload. How the portion or shared bits will be combined with bits of the of other (the second above) individual payload may be determined in any of various ways. In general, the portion of one (the first above) individual payload is combined with bits in another (the second above) individual payload based on an ordering of bits in the combined payload for error correction encoding to generate the other encoded block.

The ordering of bits in a combined individual payload for error correction encoding may be or an ordering based on a property of those bits. This property may be or include any one or more of: decoding order; decoding reliability; bit position index; and reliability weight. These properties are described above in the context of a “source” individual payload from which the portion or shared bits will be copied, but may also or instead be applied in determining how the payload or shared bits will be combined with bits of a “destination” individual payload.

Decoding order, in respect of determining how the portion or shared bits in one (the first above) individual payload will be combined with bits of another (the second above) individual payload, refers to the order of decoding bits from the other encoded block that is generated by error correction encoding the combined payload. Decoding reliability, in respect of determining how the portion or shared bits will be combined, refers to reliability of correctly decoding bits from the other encoded block, and the above-referenced sequence of reliability values is an example. Bit position index, in respect of determining how the portion or shared bits will be combined, refers to indices of bit positions in the combined payload for error correction encoding to generate the other encoded block. Reliability weight, of which the above-referenced sequence of reliability values is an example, refers to a weight related to reliability of information bit positions in the combined payload when considering the context of determining how the portion or shared bits will be combined.

These properties are examples only, and others may also or instead be used in determining how a portion or shared bits in one individual payload will be combined with bits in another individual payload. Other weight values, for example, may be used in other embodiments, and multiple properties may be used in combination.

Although not explicitly shown in FIG. 10, some embodiments may involve determining the portion of one (the first above) individual payload for combining with another (the second above) individual payload based on an ordering of bits of the one (first) individual payload, and/or determining how that portion is to be combined with the other (second) individual payload, at 1002 or 1004 for example. Some embodiments may also or instead involve combining the portion with the other (second) individual payload, at 1002 or 1004.

A self-decodable encoded block further being decodable jointly with another encoded block may enable joint decoding of the self-decodable encoded block after a decoding failure in decoding the self-decodable encoded block. A second decoding attempt, and possibly one or more subsequent attempts, may involve attempting to jointly decode a self-decodable encoded block after a decoding failure, rather than requesting a retransmission after the decoding failure. This may be referred to by way of example as a HARQ-less approach.

Some embodiments may involve, from an encoder or transmitter perspective, receiving a retransmission request, which may be or include negative acknowledgement signaling or another form of retransmission request, and retransmitting incremental redundancy (IR) information, which may be or include a redundancy version (RV) for example. In an embodiment, a method may involve receiving at 1010, by a first communication device from a second communication device, a first request for retransmission after decoding failures in both decoding a self-decodable encoded block independently and in joint decoding of the self-decodable encoded block. Of particular note is that the received request in this example is a first request for retransmission after multiple decoding failures. As illustrated at 1012, a method may also involve retransmitting, by the first communication device to the second communication device in response to the first request for retransmission, IR information for the self-decodable encoded block. Other IR information, for further encoded blocks for example, may also be transmitted at 1012.

Although FIG. 10 illustrates only transmitting IR information at 1012, it should be noted that some embodiments may involve generating and outputting IR information for a self-decodable encoded block in response to receiving a first request for retransmission after decoding failures in self-decoding and joint-decoding of a self-decodable encoded block. The generating and outputting are not separately shown in FIG. 10 to avoid further congestion in the drawing.

Embodiments may involve other features or operations that are not explicitly shown in FIG. 10. For example, selection of code rate and length for coding of one type of payload may be based, at least in part, on a code rate and length that is selected for coding another type of payload. In the above example of first and second individual payloads, an MCS for error correction encoding the second individual payload combined with the first individual payload may be selected before selecting an MCS for error correction encoding the first individual payload.

It should also be appreciated that embodiments are not limited to only two individual payloads. With reference to the first and second individual payloads above, these individual payloads may be among a number of individual payloads that includes these individual payloads and one or more others as well. Portions of multiple individual payloads may be combined with an individual payload (such as the second individual payload in this example) for error correction encoding. An MCS feature that may be implemented in such an embodiment involves selection of an MCS for error correction encoding the second individual payload combined with the portions of the multiple individual payloads from one of multiple MCS tables. The MCS tables respectively correspond to different numbers of individual payloads from which portions are combined with the second individual payload for error correction encoding. This is illustrative of an embodiment in which there are multiple MCS tables, with each corresponding to a given number of individual payloads, and potentially a number of services if the individual payloads are related to respective services, that are coupled together for potential joint decoding as disclosed herein.

Another example of features that may be provided in some embodiments but are not explicitly shown in FIG. 10 relates to signaling. Some embodiments may involve communicating, in a wireless communication network, signaling indicative of a joint coding parameter related to one or both of error correction encoding of one (the first above) individual payload and error correction encoding of another (the second above) individual payload with which a portion of the one (first) individual payload is combined.

Such communicating of signaling may involve transmitting the signaling by an encoder/encoding device or a transmitter/transmitting device that is to transmit encoded blocks, to a decoder/decoding device or a receiver/receiving device. The communicating may also or instead involve receiving the signaling by a decoder/decoding device or a receiver/receiving device from an encoder/encoding device or a transmitter/transmitting device. Signaling need not necessarily be between, or only between, communication devices by which encoded blocks are to be transmitted or received. For example, a network device such as a gNB or a base station may transmit signaling to configure joint coding parameters at one or more communication devices. Therefore, a method may involve a network device transmitting signaling, and an encoder/encoding device or a transmitter/transmitting device receiving the signaling from the network device, and/or a decoder/decoding device or a receiver/receiving device receiving the signaling from the network device.

Examples of joint coding parameters are provided elsewhere herein. In general, joint coding parameters may include any one or more of the following, and other joint coding parameters may also or instead be used in other embodiments: coding mode; MCS (which may include a respective MCS for each individual payload and/or each service in a multi-service scenario); respective priority orders for services with which the first individual payload and the second individual payload are associated; coding structure of the error correction encoding for the first individual payload; coding structure of the error correction encoding for the second individual payload combined with the portion of the first individual payload; partitioning to determine the portion of an (the first above) individual payload; respective numbers of resource elements available for services with which individual payloads (the first individual payload and the second individual payload above) are associated; respective numbers of data layers for services with which individual payloads (the first individual payload and the second individual payload above) are associated; and respective mapping methods for mapping services, with which individual payloads (the first individual payload and the second individual payload above) are associated, to data layers.

At 1050, FIG. 10 illustrates various decoding and/or receiving counterparts of the features shown at 1000. From a receiving device perspective, the receiving at 1052 is intended to represent receiving a codeword from a first communication device by a second communication device in a wireless communication network. As in other embodiments, the codeword is or includes encoded blocks generated by error correction encoding respective individual payloads. The encoded blocks include a self-decodable encoded block generated by error correction encoding a first individual payload, and another encoded block generated by error correction encoding a second individual payload with which a portion of the first individual payload is combined for error correction encoding. The self-decodable encoded block is decodable independently of other encoded block, and is also decodable jointly with the other encoded block.

FIG. 10 also illustrates operations that may be involved in decoding a codeword. At 1054, FIG. 10 illustrates decoding a first individual payload and a second individual payload from a codeword that includes a self-decodable encoded block generated by error correction encoding the first individual payload and another encoded block generated by error correction encoding the second individual payload with which a portion of the first individual payload is combined. After successful decoding (the “YES” branch at 1056), the individual payloads are output as shown at 1058, for storage to memory and/or further processing for example. The decoding at 1054 may involve decoding the self-decodable encoded block to obtain the first individual payload, and in some embodiments the decoding may involve jointly decoding (the “NO (first attempt)” branch from 1056) the other encoded block based on successful decoding of the self-decodable encoded block independently of the other encoded block. Joint decoding at 1054 may instead involve jointly decoding the self-decodable encoded block after a decoding failure (the “NO (first attempt)” branch from 1056) in decoding the self-decodable encoded block independently of the other encoded block.

The receiving and decoding at 1052, 1054 may involve different receiving device components or features, but need not be mutually exclusive. Methods may involve receiving a codeword at 1352 and decoding individual payloads from the codeword at 1354.

The “NO (first attempt)” label and return arrow from 1056 to 1054 are intended to represent a second attempt, and there may also be one or more subsequent attempts, to jointly decode a self-decodable encoded block after a decoding failure, rather than requesting a retransmission after the decoding failure. This is referred to at least above as a HARQ-less approach. If the decoding is successful after the subsequent attempt(s), then the individual payloads are output at 1058.

A method may involve transmitting at 1060, to a first communication device from a second communication device in the above example, a first request for retransmission after decoding failures in decoding the self-decodable encoded block independently of the other encoded block and in joint decoding of the self-decodable encoded block. This is represented in FIG. 10 by the “NO (final attempt)” label and arrow from 1056. The transmitted request is a first request for retransmission after multiple decoding failures, and is described by way of example at least above. IR information may be transmitted in response to the first request as shown at 1012, and from a receiving device perspective a method may involve receiving, by a second communication device from a first communication device, IR information for the self-decodable encoded block in response to the first request for retransmission that was transmitted at 1060. IR information is also described by way of example at least above. Other IR information, for further encoded blocks for example, may also be received in response to the request.

The dashed-line arrow from 1012 to 1052 in FIG. 10 is intended to represent transmission and receipt of IR information, and the return of processing to 1052 is intended to illustrate performing incremental redundancy decoding based on IR information that is obtained for the self-decodable encoded block in response to a first request for retransmission after decoding failures in decoding the self-decodable encoded block independently of the other encoded blocks and in joint decoding of the self-decodable encoded block. 1052 refers to receiving a codeword, but in the case of a retransmission the same codeword may or may not again be received. Decoding after a retransmission may also be different, and instead involve joint decoding by using a previously received codeword in combination with newly received IR information, for example.

As in other embodiments, the portion of the first individual payload for combining with the second individual payload may be determined based on an ordering of bits of the first individual payload. The ordering may be or include an ordering based on a property of the bits of the first individual payload. The property may, as described by way of example at least above, be or include any one or more of: decoding reliability; decoding order; bit position index; and reliability weight.

The portion of one (the first above) individual payload may be combined with another (the second above) individual payload based on an ordering of bits in a combined payload for error correction encoding to generate the other encoded block. The ordering of the bits for error correction encoding to generate the other encoded block may be or include an ordering based on a property of the bits for error correction encoding to generate the other encoded block. Examples of such a property as described elsewhere here include the following, any one or more of which may be a basis for ordering of bits in a combined payload: decoding order of decoding the bits from the other encoded block; decoding reliability of decoding bits from the other encoded block; bit position index; and reliability weight.

As also described at least above, these example properties are are examples only, and others may also or instead be used in determining the portion or shared bits to be combined, and/or how the portion or shared bits in one individual payload will be combined with bits in another individual payload. Other weight values, for example, may be used in other embodiments, and multiple properties may be used in combination.

Other features not explicitly shown in FIG. 10 may be provided or supported, or may at least affect decoding-side or receiving-side operations. For example, MCS selection for error correction encoding the second individual payload combined with the first individual payload before selecting an MCS for error correction encoding the first individual payload may be implemented as encoding-side or transmitting-side operations, but the selected MCSs also affect decoding-side or receiving-side operations.

Additional MCS features for embodiments that involve more than two individual payloads are also described at least above, and such features may affect decoding-side or receiving-side operations as well. For example, the first individual payload and the second individual payload may be two individual payloads of a larger number of individual payloads, and portions of multiple individual payloads may be combined with the second individual payload for error correction encoding. An MCS for the second individual payload combined with the portions of the multiple individual payloads may be or include an MCS from one of multiple MCS tables respectively corresponding to different numbers of individual payloads from which portions are combined with the second individual payload for error correction encoding.

A method consistent with the example shown at 1050 may involve communicating signaling indicative of a joint coding parameter related to one or both of the error correction encoding of the first individual payload and the error correction encoding of the second individual payload with which a portion of the first individual payload is combined. Examples of such communicating, and examples of joint coding parameters of which such signaling may be indicative, are provided at least above.

The present disclosure encompasses various embodiments, including not only method embodiments, but also other embodiments such as apparatus embodiments and embodiments related to non-transitory computer readable storage media. Embodiments may incorporate, individually or in combinations, the features disclosed herein.

An apparatus may include a processor and a non-transitory computer readable storage medium, coupled to the processor, storing programming for execution by the processor. In FIG. 3, for example, the processors 210, 260, 276 may each be or include one or more processors, and each memory 208, 258, 278 is an example of a non-transitory computer readable storage medium, in an ED 110 and a TRP 170, 172. A non-transitory computer readable storage medium need not necessarily be provided only in combination with a processor, and may be provided separately in a computer program product, for example.

As an illustrative example, programming stored in or on a non-transitory computer readable storage medium may include instructions to or to cause a processor to transmit, by a first communication device to a second communication device in a wireless communication network, a codeword that includes encoded blocks generated by error correction encoding respective individual payloads. The encoded blocks include a self-decodable encoded block generated by error correction encoding a first individual payload, and another encoded block generated by error correction encoding a second individual payload with which a portion of the first individual payload is combined for error correction encoding.

In another embodiment, programming stored in or on a non-transitory computer readable storage medium may include instructions to, or to cause a processor to: obtain a first individual payload and a second individual payload; error correction encode the first individual payload to generate a self-decodable encoded block; error correction encode the second individual payload with which a portion of the first individual payload is combined for error correction encoding, to generate another encoded block; and output a codeword comprising the self-decodable encoded block and the other encoded block.

In these and other embodiments, the portion of the first individual payload may be determined for combining with the second individual payload based on an ordering of bits of the first individual payload.

Embodiments related to apparatus or non-transitory computer readable storage media may include any one or more of the following features, for example, which are also discussed elsewhere herein:
programming may further include instructions to, or to cause a processor to obtain the first individual payload and the second individual payload;
programming may further include instructions to, or to cause a processor to error correction encode the first individual payload to generate the self-decodable encoded block and error correction encoding the second individual payload combined with the portion of the first individual payload to generate the other encoded block;
the self-decodable encoded block further being decodable jointly with the other encoded block may enable joint decoding of the other encoded block based on successful decoding of the self-decodable encoded block independently of the other encoded block;
the self-decodable encoded block further being decodable jointly with the other encoded block may enable joint decoding of the self-decodable encoded block after a decoding failure in decoding the self-decodable encoded block independently of the other encoded block; the ordering may be or include an ordering based on a property of the bits of the first individual payload;
the property may be or include any one or more of: decoding reliability; decoding order; bit position index; and reliability weight;
the portion of the first individual payload may be combined with the second individual payload based on an ordering of bits for error correction encoding to generate the other encoded block;
the ordering of the bits for error correction encoding to generate the other encoded block may be or include an ordering based on a property of the bits for error correction encoding to generate the other encoded block;
the property of the bits for error correction encoding to generate the other encoded block may be or include any one or more of: decoding order of decoding the bits from the other encoded block; decoding reliability of decoding bits from the other encoded block; bit position index; and reliability weight;
an MCS for error correction encoding the second individual payload combined with the first individual payload may be selected before selecting an MCS for error correction encoding the first individual payload;
the first individual payload and the second individual payload may be or include individual payloads of a plurality of individual payloads;
portions of multiple individual payloads of the plurality of individual payloads may be combined with the second individual payload for error correction encoding;
an MCS for error correction encoding the second individual payload combined with the portions of the multiple individual payloads may be selected from one of multiple MCS tables respectively corresponding to different numbers of individual payloads from which portions are combined with the second individual payload for error correction encoding;
programming may further include instructions to, or to cause a processor to communicate, in the wireless communication network, signaling indicative of a joint coding parameter related to one or both of the error correction encoding of the first individual payload and the error correction encoding of the second individual payload with which a portion of the first individual payload is combined;
the signaling is indicative of any one or more of: coding mode; an MCS; respective priority orders for services with which the first individual payload and the second individual payload are associated; coding structure of the error correction encoding for the first individual payload; coding structure of the error correction encoding for the second individual payload combined with the portion of the first individual payload; partitioning to determine the portion of the first individual payload; respective numbers of resource elements available for services with which the first individual payload and the second individual payload are associated; respective numbers of data layers for services with which the first individual payload and the second individual payload are associated; respective mapping methods for mapping services, with which the first individual payload and the second individual payload are associated, to data layers.

Programming stored in or on a non-transitory computer readable storage medium may also or instead include instructions to or to cause a processor to receive, from a first communication device by a second communication device in a wireless communication network, a codeword that includes encoded blocks generated by error correction encoding respective individual payloads. The encoded blocks include a self-decodable encoded block generated by error correction encoding a first individual payload, and another encoded block generated by error correction encoding a second individual payload with which a portion of the first individual payload is combined for error correction encoding.

In another embodiment, programming stored in or on a non-transitory computer readable storage medium may include instructions to, or to cause a processor to: decode a first individual payload and a second individual payload from a codeword that comprises a self-decodable encoded block generated by error correction encoding the first individual payload and another encoded block generated by error correction encoding the second individual payload with which a portion of the first individual payload is combined; and output the first individual payload and the second individual payload.

In these and other embodiments, the portion of the first individual payload may be determined for combining with the second individual payload based on an ordering of bits of the first individual payload.

Embodiments related to apparatus or non-transitory computer readable storage media may include any one or more of the following features, for example, which are also discussed elsewhere herein:
programming may further include instructions to, or to cause a processor to, decode the self-decodable encoded block to obtain the first individual payload;
programming may further include instructions to, or to cause a processor to: decode the self-decodable encoded block independently of the other encoded block; and jointly decode the other encoded block based on successful decoding of the self-decodable encoded block independently of the other encoded block;
programming may further include instructions to, or to cause a processor to, jointly decode the self-decodable encoded block after a decoding failure in decoding the self-decodable encoded block independently of the other encoded block;
the ordering may be or include an ordering based on a property of the bits of the first individual payload;
the property may be or include any one or more of: decoding reliability; decoding order; bit position index; and reliability weight;
the portion of the first individual payload may be combined with the second individual payload based on an ordering of bits for error correction encoding to generate the other encoded block;
the ordering of the bits for error correction encoding to generate the other encoded block may be or include an ordering based on a property of the bits for error correction encoding to generate the other encoded block;
the property of the bits for error correction encoding to generate the other encoded block may be or include any one or more of: decoding order of decoding the bits from the other encoded block; decoding reliability of decoding bits from the other encoded block; bit position index; and reliability weight;
an MCS for error correction encoding the second individual payload combined with the first individual payload may be selected before selecting an MCS for error correction encoding the first individual payload;
the first individual payload and the second individual payload may be or include individual payloads of a plurality of individual payloads;
portions of multiple individual payloads of the plurality of individual payloads may be combined with the second individual payload for error correction encoding;
an MCS for error correction encoding the second individual payload combined with the portions of the multiple individual payloads may be selected from one of multiple MCS tables respectively corresponding to different numbers of individual payloads from which portions are combined with the second individual payload for error correction encoding;
programming may further include instructions to, or to cause a processor to communicate, in the wireless communication network, signaling indicative of a joint coding parameter related to one or both of the error correction encoding of the first individual payload and the error correction encoding of the second individual payload with which a portion of the first individual payload is combined;
the signaling is indicative of any one or more of: coding mode; an MCS; respective priority orders for services with which the first individual payload and the second individual payload are associated; coding structure of the error correction encoding for the first individual payload; coding structure of the error correction encoding for the second individual payload combined with the portion of the first individual payload; partitioning to determine the portion of the first individual payload; respective numbers of resource elements available for services with which the first individual payload and the second individual payload are associated; respective numbers of data layers for services with which the first individual payload and the second individual payload are associated; respective mapping methods for mapping services, with which the first individual payload and the second individual payload are associated, to data layers.

Embodiments disclosed herein encompass various aspects of what may be referred to as HARQ-less intra-UE MA coding that may be especially suited to hard-output codes. Embodiments may be applied to a wide range of communication networks, such as 5G+, 6G, WiFi, non-terrestrial networks (NTNs), and distributed or self-organized networks.

Self-decodability may be provided, for different types of payloads such as URLLC data and eMBB data for example.

High reliability may also or instead be provided for certain types of payloads. For example, URLLC performance may be enhanced even when eMBB decoding fails.

Some embodiments may provide lower latency. Shared bits may be copied from a URLLC payload and combined with bits of another payload such as an eMBB payload based on decoding order of the eMBB payload, for example, to support an earlier start of joint decoding of the URLLC payload before all eMBB symbols are received.

Performance improvement may be realized in significant slope gain of payloads with higher decoding priority, such as URLLC payloads, especially at low BLER.

A coding approach that supports a second (joint) decoding attempt without HARQ as disclosed herein may provide improved resilience or reliability, lower latency, and better performance relative to conventional HARQ approaches.

With multiple payloads being coupled and encoded into a long codeword to enable self-decodability and joint-decodability, diverse KPI requirements can be supported, for multiple payloads or services for example. Embodiments may also or instead support increased flexibility for multi-service scenarios or other applications that involve different types of payloads.

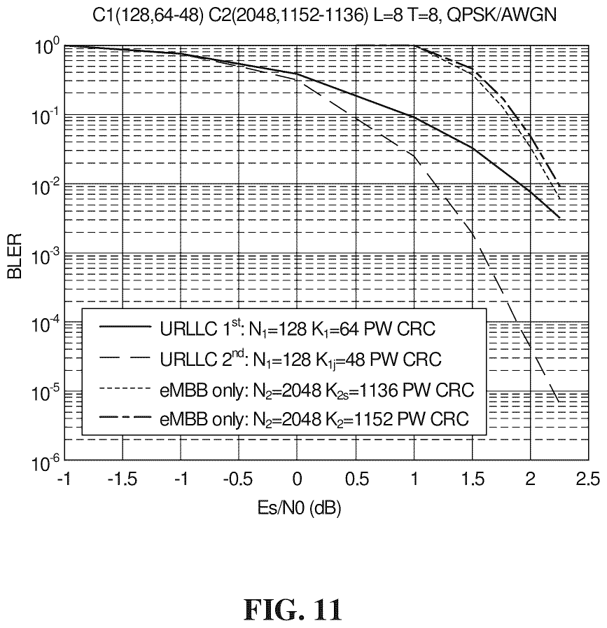

FIG. 11 is a plot of simulation results for an example scenario.

In FIG. 11, “URLLC 1^{st}” indicates self-decoding performance for URLLC and a first attempt, “URLLC 2^{nd}” indicates joint-decoding performance for URLLC and a second attempt, “eMBB only: N₂=2048 K₂ₛ=1136 PW CRC” indicates self-decoding performance for eMBB alone (without coupling as disclosed herein), and “eMBB only: N₂=2048 K₂=1152 PW CRC” indicates joint-decoding performance of eMBB (with coupling as disclosed herein). Similar or different results may be observed under similar or different simulation conditions relative to those shown in FIG. 11, and/or in deployments of embodiments.

In FIG. 11, the other notation is as follows:
C1(128,64-48) refers to a first code block 1, with 128 code bits and 64 information bits, where 48 are exclusive information bits and 16 are shared information bits;
C2(2048,1152-1136) refers to code block 2, with 2048 code bits and 64 information bits, where 48 are exclusive information bits and 16 are shared information bits;
L=8 refers to the list size in a polar SCL decoder;
T=8 refers to the CRC/PC check times in a polar CA/PC-SCL decoder, in which the decoder checks the first T paths and if one passes CRC/PC check, then output that path as the decoding result;
N₁=128 K₁=64 refers to code length 128 and information (or payload length) 64;
PW CRC refers to the polar code construction using polarization weight (PW), and CRC-aided polar codes;
N₁=128 K₁ⱼ=48 refers to code length 128 and information (or payload length) 48;
N₂=2048 K₂ₛ=1136 refers to code length 2048 and information (or payload length) 1136;
N₂=2048 K₂=1152 refers to code length 2048 and information (or payload length) 1152.

These are example simulation conditions, and other simulations and/or deployments may be under similar or different conditions.

As shown, the joint decoding performance of URLLC after a second decoding attempt is significantly better than after a first decoding attempt. It is worth noting that the slope is much steeper and thus improved, making embodiments that support a second decoding attempt very suitable to operate in a high SNR and low BLER region. This is exactly the target operation region of URLLC.

FIG. 11 also shows that to support joint-decoding, eMBB performance with coupling is slightly worse than eMBB performance without coupling. This is because additional payload bits are attached to original eMBB payload bits, making the effective code rate higher than in the case without coupling. However, this performance cost may be considered negligible, or at least a worthwhile trade-off, relative to the benefits in enhanced URLLC reliability.

Although this disclosure has been described with reference to illustrative embodiments, this description is not intended to be construed in a limiting sense. Various modifications and combinations of the illustrative embodiments, as well as other embodiments of the disclosure, will be apparent to persons skilled in the art upon reference to the description. It is therefore intended that the appended claims encompass any such modifications or embodiments.

Features disclosed herein in the context of method embodiments, for example, may also or instead be implemented in apparatus or computer program product embodiments. In addition, although embodiments are described primarily in the context of methods and apparatus, other implementations are also contemplated, as instructions stored on one or more non-transitory computer-readable media, for example. Such media could store programming or instructions to perform any of various methods consistent with the present disclosure.

Although aspects of the present invention have been described with reference to specific features and embodiments thereof, various modifications and combinations can be made thereto without departing from the invention. The description and drawings are, accordingly, to be regarded simply as an illustration of some embodiments of the invention as defined by the appended claims, and are contemplated to cover any and all modifications, variations, combinations or equivalents that fall within the scope of the present invention. Therefore, although embodiments and potential advantages have been described in detail, various changes, substitutions and alterations can be made herein without departing from the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

Moreover, any module, component, or device exemplified herein that executes instructions may include or otherwise have access to a non-transitory computer readable or processor readable storage medium or media for storage of information, such as computer readable or processor readable instructions, data structures, program modules, and/or other data. A non-exhaustive list of examples of non-transitory computer readable or processor readable storage media includes magnetic cassettes, magnetic tape, magnetic disk storage or other magnetic storage devices, optical disks such as compact disc read-only memory (CD-ROM), digital video discs or digital versatile disc (DVDs), Blu-ray Disc™, or other optical storage, volatile and non-volatile, removable and nonremovable media implemented in any method or technology, random-access memory (RAM), read-only memory (ROM), electrically erasable programmable read-only memory (EEPROM), flash memory or other memory technology. Any such non-transitory computer readable or processor readable storage media may be part of a device or accessible or connectable thereto. Any application or module herein described may be implemented using instructions that are readable and executable by a computer or processor may be stored or otherwise held by such non-transitory computer readable or processor readable storage media.

1. A method comprising:
transmitting, by a first communication device to a second communication device in a wireless communication network, a codeword comprising a plurality of encoded blocks generated by error correction encoding respective individual payloads,
the plurality of encoded blocks comprising a self-decodable encoded block generated by error correction encoding a first individual payload, and another encoded block generated by error correction encoding a second individual payload combined with a portion of the first individual payload, the portion of the first individual payload being determined for combining with the second individual payload based on an ordering of bits of the first individual payload,
the self-decodable encoded block being decodable independently of the another encoded block, and further being decodable jointly with the another encoded block.

2. The method of claim 1, further comprising:
obtaining the first individual payload and the second individual payload; and
error correction encoding the first individual payload to generate the self-decodable encoded block and error correction encoding the second individual payload combined with the portion of the first individual payload to generate the another encoded block.

3. The method of claim 1, wherein the ordering comprises an ordering based on a property of the bits of the first individual payload, and wherein the property comprises any one or more of: decoding reliability; decoding order; bit position index; or reliability weight.

4. The method of claim 1, wherein the portion of the first individual payload is combined with the second individual payload based on an ordering of bits for error correction encoding to generate the another encoded block, wherein the ordering of the bits for error correction encoding to generate the another encoded block comprises an ordering based on a property of the bits for error correction encoding to generate the another encoded block, wherein the property of the bits for error correction encoding to generate the another encoded block comprises any one or more of: decoding order of decoding bits from the another encoded block; decoding reliability of decoding the bits from the another encoded block; bit position index; or reliability weight.

5. The method of claim 1, further comprising:
communicating, in the wireless communication network, signaling indicative of a joint coding parameter related to at least one of the error correction encoding of the first individual payload or the error correction encoding of the second individual payload combined with the portion of the first individual payload, and wherein the signaling is indicative of any one or more of:
coding mode;
a modulation and coding scheme (MCS);
respective priority orders for services with which the first individual payload and the second individual payload are associated;
coding structure of the error correction encoding for the first individual payload;
coding structure of the error correction encoding for the second individual payload combined with the portion of the first individual payload;
partitioning to determine the portion of the first individual payload;
respective numbers of resource elements available for services with which the first individual payload and the second individual payload are associated;
respective numbers of data layers for services with which the first individual payload and the second individual payload are associated; or
respective mapping methods for mapping services, with which the first individual payload and the second individual payload are associated, to data layers.

6. A method comprising:
receiving, from a first communication device by a second communication device in a wireless communication network, a codeword comprising a plurality of encoded blocks generated by error correction encoding respective individual payloads,
the plurality of encoded blocks comprising a self-decodable encoded block generated by error correction encoding a first individual payload, and another encoded block generated by error correction encoding a second individual payload combined with a portion of the first individual payload, the portion of the first individual payload being determined for combining with the second individual payload based on an ordering of bits of the first individual payload,
the self-decodable encoded block being decodable independently of the another encoded block, and further being decodable jointly with the another encoded block.

7. The method of claim 6, further comprising:
decoding the self-decodable encoded block to obtain the first individual payload.

8. The method of claim 6, further comprising:
decoding the self-decodable encoded block independently of the another encoded block; and
jointly decoding the another encoded block based on successful decoding of the self-decodable encoded block independently of the another encoded block.

9. The method of claim 6, further comprising:
jointly decoding the self-decodable encoded block after a decoding failure in decoding the self-decodable encoded block independently of the another encoded block.

10. The method of claim 6, further comprising:
communicating, in the wireless communication network, signaling indicative of a joint coding parameter related to at least one of the error correction encoding of the first individual payload or the error correction encoding of the second individual payload combined with the portion of the first individual payload, and wherein the signaling is indicative of any one or more of:
coding mode;
a modulation and coding scheme (MCS);
respective priority orders for services with which the first individual payload and the second individual payload are associated;
coding structure of the error correction encoding for the first individual payload;
coding structure of the error correction encoding for the second individual payload combined with the portion of the first individual payload;
partitioning to determine the portion of the first individual payload;
respective numbers of resource elements available for services with which the first individual payload and the second individual payload are associated;
respective numbers of data layers for services with which the first individual payload and the second individual payload are associated; or
respective mapping methods for mapping services, with which the first individual payload and the second individual payload are associated, to data layers.

11. An apparatus comprising:
at least one processor; and
a non-transitory computer readable storage medium, coupled to the at least one processor, storing programming for execution by the at least one processor, the programming including instructions to cause the apparatus to perform:
transmitting, by a first communication device to a second communication device in a wireless communication network, a codeword comprising a plurality of encoded blocks generated by error correction encoding respective individual payloads,
the plurality of encoded blocks comprising a self-decodable encoded block generated by error correction encoding a first individual payload, and another encoded block generated by error correction encoding a second individual payload combined with a portion of the first individual payload, the portion of the first individual payload being determined for combining with the second individual payload based on an ordering of bits of the first individual payload,
the self-decodable encoded block being decodable independently of the another encoded block, and further being decodable jointly with the another encoded block.

12. The apparatus of claim 11, the programming further including instructions to cause the apparatus to perform:
obtaining the first individual payload and the second individual payload; and
error correction encoding the first individual payload to generate the self-decodable encoded block and error correction encoding the second individual payload combined with the portion of the first individual payload to generate the another encoded block.

13. The apparatus of claim 11, wherein the ordering comprises an ordering based on a property of the bits of the first individual payload, and wherein the property comprises any one or more of: decoding reliability; decoding order; bit position index; or reliability weight.

14. The apparatus of claim 11, wherein the portion of the first individual payload is combined with the second individual payload based on an ordering of bits for error correction encoding to generate the another encoded block, wherein the ordering of the bits for error correction encoding to generate the another encoded block comprises an ordering based on a property of the bits for error correction encoding to generate the another encoded block, wherein the property of the bits for error correction encoding to generate the another encoded block comprises any one or more of: decoding order of decoding bits from the another encoded block; decoding reliability of decoding the bits from the another encoded block; bit position index; or reliability weight.

15. The apparatus of claim 11, the programming further including instructions to:
communicate, in the wireless communication network, signaling indicative of a joint coding parameter related to at least one of the error correction encoding of the first individual payload or the error correction encoding of the second individual payload combined with the portion of the first individual payload, and wherein the signaling is indicative of any one or more of:
coding mode;
a modulation and coding scheme (MCS);
respective priority orders for services with which the first individual payload and the second individual payload are associated;
coding structure of the error correction encoding for the first individual payload;
coding structure of the error correction encoding for the second individual payload combined with the portion of the first individual payload;
partitioning to determine the portion of the first individual payload;
respective numbers of resource elements available for services with which the first individual payload and the second individual payload are associated;
respective numbers of data layers for services with which the first individual payload and the second individual payload are associated; or
respective mapping methods for mapping services, with which the first individual payload and the second individual payload are associated, to data layers.

16. An apparatus comprising:
at least one processor; and
a non-transitory computer readable storage medium, coupled to the at least one processor, storing programming for execution by the at least one processor, the programming including instructions to cause the apparatus to perform:
receiving, from a first communication device by a second communication device in a wireless communication network, a codeword comprising a plurality of encoded blocks generated by error correction encoding respective individual payloads,
the plurality of encoded blocks comprising a self-decodable encoded block generated by error correction encoding a first individual payload, and another encoded block generated by error correction encoding a second individual payload combined with a portion of the first individual payload, the portion of the first individual payload being determined for combining with the second individual payload based on an ordering of bits of the first individual payload,
the self-decodable encoded block being decodable independently of the another encoded block, and further being decodable jointly with the another encoded block.

17. The apparatus of claim 16, the programming further including instructions to perform:
decoding the self-decodable encoded block to obtain the first individual payload.

18. The apparatus of claim 16, the programming further including instructions to perform:
decoding the self-decodable encoded block independently of the another encoded block; and
jointly decoding the another encoded block based on successful decoding of the self-decodable encoded block independently of the another encoded block.

19. The apparatus of claim 16, the programming further including instructions to perform:
jointly decoding the self-decodable encoded block after a decoding failure in decoding the self-decodable encoded block independently of the another encoded block.

20. The apparatus of claim 16, the programming further including instructions to perform:
communicating, in the wireless communication network, signaling indicative of a joint coding parameter related to at least one of the error correction encoding of the first individual payload or the error correction encoding of the second individual payload combined with the portion of the first individual payload, and wherein the signaling is indicative of any one or more of:
coding mode;
a modulation and coding scheme (MCS);
respective priority orders for services with which the first individual payload and the second individual payload are associated;
coding structure of the error correction encoding for the first individual payload;
coding structure of the error correction encoding for the second individual payload combined with the portion of the first individual payload;
partitioning to determine the portion of the first individual payload;
respective numbers of resource elements available for services with which the first individual payload and the second individual payload are associated;
respective numbers of data layers for services with which the first individual payload and the second individual payload are associated; or
respective mapping methods for mapping services, with which the first individual payload and the second individual payload are associated, to data layers.
